(19) United States
(12) Patent Application Publication
(10) Pub. No.: US 2024/0090303 A1
(43) Pub. Date: Mar. 14, 2024

(54) DISPLAY DEVICE AND MANUFACTURING METHOD OF DISPLAY DEVICE

(71) Applicant: Semiconductor Energy Laboratory Co., Ltd., Atsugi-shi, Kanagawa-ken (JP)

(72) Inventors: Daisuke KUBOTA, Atsugi (JP); Ryo HATSUMI, Hadano (JP); Yasuhiro NIIKURA, Komae (JP); Shunpei YAMAZAKI, Setagaya (JP)

(21) Appl. No.: 18/273,085

(22) PCT Filed: Jan. 18, 2022
(86) PCT No.: PCT/IB2022/050365

§ 371 Date: Jul. 19, 2023

(30) Foreign Application Priority Data
Jan. 28, 2021 (JP) 2021-011705

(51) Int. Cl. H10K 59/00; H10K 39/34; H10K 59/12

(52) U.S. Cl. CPC H10K 59/771; H10K 39/34; H10K 59/1201

(57) ABSTRACT

A display device having a function of detecting an object that is in contact with or approaches a display portion is provided. The display device includes a light-emitting element and a light-receiving element. The light-emitting element includes a first pixel electrode, a first functional layer, a light-emitting layer, a common layer, and a common electrode. The light-receiving element includes a second pixel electrode, a second functional layer, a light-receiving layer, the common layer, and the common electrode. The first functional layer includes one of a hole-injection layer and an electron-injection layer. The second functional layer includes one of a hole-transport layer and an electron-transport layer. The common layer has a function of the other of the hole-injection layer and the electron-injection layer in the light-emitting element and has a function of the other of the hole-transport layer and the electron-transport layer in the light-receiving element.

### TECHNICAL FIELD

One embodiment of the present invention relates to a display device. One embodiment of the present invention relates to a manufacturing method of a display device.

Note that one embodiment of the present invention is not limited to the above technical field. Examples of a technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, display devices have been used in a variety of devices such as information terminal devices such as smartphones, tablet terminals, and laptop PCs, television devices, and monitor devices. In addition, display devices have been required to have a variety of functions such as a touch sensor function and a function of capturing images of fingerprints for authentication, in addition to a function of displaying images.

Light-emitting apparatuses including light-emitting elements (also referred to as light-emitting devices) have been developed as display devices, for example. In particular, light-emitting elements (also referred to as EL elements or EL devices) utilizing an electroluminescence (EL) phenomenon have features such as ease of reduction in thickness and weight, high-speed response to an input signal, and driving with a direct-constant voltage source, and have been applied to display devices. For example, Patent Document 1 discloses a flexible light-emitting apparatus to which an organic EL element (also referred to as an organic EL device) is applied.

### REFERENCE

### Patent Document

[Patent Document 1] Japanese Published Patent Application No. 2014-197522

### SUMMARY OF THE INVENTION

### Problems to be Solved by the Invention

An object of one embodiment of the present invention is to provide a display device having a function of detecting an object that is in contact with or approaches a display portion and a manufacturing method thereof. An object of one embodiment of the present invention is to provide a display device having a function of performing authentication and a manufacturing method thereof. An object of one embodiment of the present invention is to provide a display device with a high aperture ratio and a manufacturing method thereof. An object of one embodiment of the present invention is to provide a small display device and a manufacturing method thereof. An object of one embodiment of the present invention is to provide a highly reliable display device and a manufacturing method thereof. An object of one embodiment of the present invention is to provide a novel display device and a manufacturing method thereof.

Note that the description of these objects does not preclude the presence of other objects. Note that in one embodiment of the present invention, there is no need to achieve all the objects. Note that other objects can be derived from the description of the specification, the drawings, the claims, and the like.

### Means for Solving the Problems

One embodiment of the present invention is a display device that includes a light-emitting element and a light-receiving element. The light-emitting element includes a first pixel electrode, a first functional layer, a light-emitting layer, a common layer, and a common electrode. The light-receiving element includes a second pixel electrode, a second functional layer, a light-receiving layer, the common layer, and the common electrode. The first functional layer includes one of a hole-injection layer and an electron-injection layer. The second functional layer includes one of a hole-transport layer and an electron-transport layer. In the light-emitting element, the common layer has a function of the other of the hole-injection layer and the electron-injection layer.

Alternatively, in the above embodiment, the first functional layer and the second functional layer may be separated from each other.

Alternatively, in the above embodiment, the display device may further include a first transistor and a second transistor. One of a source and a drain of the first transistor may be electrically connected to the first pixel electrode. One of a source and a drain of the second transistor may be electrically connected to the second pixel electrode. The first transistor and the second transistor may contain silicon or a metal oxide in a channel formation region.

Alternatively, one embodiment of the present invention is a method including a first step of forming a first pixel electrode, a second pixel electrode, and a connection electrode; a second step of depositing a light-emitting film over the first pixel electrode and the second pixel electrode; a third step of forming a first sacrificial film over the light-emitting film and the connection electrode; a fourth step of exposing the second pixel electrode by etching the first sacrificial film and the light-emitting film, and forming a light-emitting layer over the first pixel electrode and a first sacrificial layer over the light-emitting layer and the connection electrode; a fifth step of depositing a light-receiving film over the light-emitting layer and the second pixel electrode; a sixth step of forming a second sacrificial film over the light-receiving film and the connection electrode; a seventh step of, by etching the second sacrificial film and the light-receiving film, forming a light-receiving layer over the second pixel electrode and forming a second sacrificial layer over the light-receiving layer and the connection electrode; an eighth step of removing the first sacrificial layer and the second sacrificial layer; a ninth step of forming a common layer over the light-emitting layer and the light-receiving layer; and a tenth step of forming a common electrode so that the common electrode includes a region in contact with the common layer and the connection electrode.

Alternatively, in the above embodiment, the common layer may have a function of one of a hole-injection layer and an electron-injection layer in a light-emitting element including the first pixel electrode, the light-emitting layer, the common layer, and the common electrode.

Alternatively, in the above embodiment, the method may include an eleventh step of depositing a first functional film over the first pixel electrode and the second pixel electrode in a period between the first step and the second step. In the fourth step, the first functional film may be etched to form a first functional layer over the first pixel electrode. The method may include a twelfth step of depositing a second functional film over the first sacrificial layer and the second pixel electrode in a period between the fourth step and the fifth step. In the seventh step, the second functional film may be etched to form a second functional layer over the second pixel electrode. The first functional layer may include the other of the hole-injection layer and the electron-injection layer. The second functional layer may include one of a hole-transport layer and an electron-transport layer.

Alternatively, in the above embodiment, the light-emitting film, the light-receiving film, and the common layer may be formed by an evaporation method using a shielding mask.

Alternatively, in the above embodiment, the first sacrificial film and the second sacrificial film may include the same metal film, alloy film, metal oxide film, semiconductor film, or inorganic insulating film. In the fourth step, the light-emitting film may be etched by dry etching using an etching gas that does not contain oxygen as a main component. In the eighth step, the first sacrificial layer and the second sacrificial layer may be removed by wet etching using a tetramethyl ammonium hydroxide aqueous solution, dilute hydrofluoric acid, oxalic acid, phosphoric acid, acetic acid, nitric acid, or a mixed solution thereof.

Alternatively, in the above embodiment, the first sacrificial film and the second sacrificial film may include aluminum oxide.

Alternatively, in the above embodiment, the manufacturing method of a display device may include a fourteenth step of forming a protective layer over the common electrode after the tenth step.

### Effect of the Invention

According to one embodiment of the present invention, it is possible to provide a display device having a function of detecting an object that is in contact with or approaches a display portion and a manufacturing method thereof. According to one embodiment of the present invention, it is possible to provide a display device having a function of performing authentication and a manufacturing method thereof. According to one embodiment of the present invention, it is possible to provide a display device with a high aperture ratio and a manufacturing method thereof. According to one embodiment of the present invention, it is possible to provide a small display device and a manufacturing method thereof. According to one embodiment of the present invention, it is possible to provide a highly reliable display device and a manufacturing method thereof. According to one embodiment of the present invention, it is possible to provide a novel display device and a manufacturing method thereof.

Note that the description of these effects does not preclude the presence of other effects. Note that one embodiment of the present invention does not necessarily have all of these effects. Note that other effects can be derived from the description of the specification, the drawings, and the claims.

### BRIEF DESCRIPTION OF THE DRAWINGS

FIG. 1A to FIG. 1E are cross-sectional views illustrating structure examples of display devices.

FIG. 1F is a diagram illustrating an example of a captured image.

FIG. 2A and FIG. 2B are top views each illustrating a structure example of a display device.

FIG. 3A and FIG. 3B are top views each illustrating a structure example of a display device.

FIG. 4A is a top view illustrating a structure example of a display device. FIG. 4B is a diagram illustrating a light-receiving range of a light-receiving element.

FIG. 5 is a top view illustrating a structure example of a display device.

FIG. 6A to FIG. 6E are cross-sectional views illustrating structure examples of a display device.

FIG. 7A to FIG. 7D are cross-sectional views illustrating an example of a manufacturing method of a display device.

FIG. 8A to FIG. 8C are cross-sectional views illustrating an example of a manufacturing method of a display device.

FIG. 9A to FIG. 9D are cross-sectional views illustrating an example of a manufacturing method of a display device.

FIG. 10A to FIG. 10C are cross-sectional views illustrating an example of a manufacturing method of a display device.

FIG. 11A to FIG. 11C are cross-sectional views illustrating an example of a manufacturing method of a display device.

FIG. 12A is a top view illustrating a structure example of a display device. FIG. 12B and FIG. 12C are cross-sectional views illustrating a structure example of a display device.

FIG. 13A is a top view illustrating a structure example of a display device. FIG. 13B is a cross-sectional view illustrating a structure example of a display device.

FIG. 14 is a perspective view illustrating a structure example of a display device.

FIG. 15 is a cross-sectional view illustrating a structure example of a display device.

FIG. 16 is a cross-sectional view illustrating a structure example of a display device.

FIG. 17 is a cross-sectional view illustrating a structure example of a display device.

FIG. 18 is a cross-sectional view illustrating a structure example of a display device.

FIG. 19 is a cross-sectional view illustrating a structure example of a display device.

FIG. 20A to FIG. 20D are cross-sectional views each illustrating a structure example of a light-emitting element.

FIG. 21A and FIG. 21B are diagrams each illustrating a structure example of a display device.

FIG. 22A to FIG. 22G are diagrams illustrating structure examples of a display device.

FIG. 23A to FIG. 23E are diagrams each illustrating an example of an electronic device.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the present invention described below, the same reference numerals are commonly used for the same portions or portions having similar functions in different drawings, and a repeated description thereof is omitted. Moreover, similar functions are denoted by the same hatching pattern and are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that ordinal numbers such as “first” and “second” in this specification are used in order to avoid confusion among components and do not limit the number of components.

In addition, in this specification and the like, the term “film” and the term “layer” can be interchanged with each other. For example, in some cases, the term “conductive layer” or “insulating layer” can be interchanged with the term “conductive film” or “insulating film.”

Note that in this specification and the like, an EL layer refers to a layer that contains at least a light-emitting substance (also referred to as a light-emitting layer) or a stack including the light-emitting layer provided between a pair of electrodes of a light-emitting element.

In this specification and the like, a display panel that is one embodiment of a display device has a function of displaying (outputting), for example, an image on (to) a display surface. Therefore, the display panel is one embodiment of an output device.

Furthermore, in this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

### Embodiment 1

In this embodiment, structure examples of a display device according to one embodiment of the present invention and an example of a method for manufacturing the display device will be described.

The display device according to one embodiment of the present invention includes a display portion where a plurality of pixels arranged in a matrix. The pixel includes a plurality of subpixels, and one light-emitting element (also referred to as light-emitting device) is provided for one subpixel. A plurality of subpixels provided for the same pixel can have a function of emitting light of different colors.

Light-emitting elements each include a pair of electrodes and a light-emitting layer therebetween. The light-emitting elements are preferably organic EL elements (organic electroluminescent elements). Two or more light-emitting elements that emit different colors include light-emitting layers containing different materials. For example, when three kinds of light-emitting elements that emit red (R) light, green (G) light, and blue (B) light are included, a full-color display device can be achieved.

Here, in the case where the light-emitting layers are separately formed between light-emitting elements of different colors, an evaporation method using a shadow mask such as a metal mask is known. However, this method causes a deviation from the designed shape and position of an island-shaped organic film due to various influences such as the accuracy of the metal mask, the positional deviation between the metal mask and a substrate, a warp of the metal mask, and expansion of the outline of a deposited film die to vapor scattering, for example; accordingly, it is difficult to achieve high resolution and high aperture ratio. Therefore, a measure has been taken for pseudo increase in resolution (also referred to pixel density) by employing unique pixel arrangement such as PenTile arrangement, for example.

In one embodiment of the present invention, fine patterning of light-emitting layers is performed without a shadow mask such as a metal mask. This enables further miniaturization of subpixels compared to the case of separately forming light-emitting layers by using a shadow mask and an increase in pixel aperture ratio. Moreover, since light-emitting layers can be formed separately, it is possible to achieve a display device that performs extremely clear display with high contrast and high display quality.

Miniaturization of subpixels enables providing subpixels that do not contribute to display in a pixel. For example, in addition to a subpixel that includes a light-emitting element, a subpixel that includes a light-receiving element (also referred to as a light-receiving device) can be provided in a pixel. Even in such a case, the display device according to one embodiment of the present invention can inhibit a decrease in pixel density. For example, the pixel density can be higher than or equal to 400 ppi, can be higher than or equal to 1000 ppi, can be higher than or equal to 3000 ppi, or can be higher than or equal to 5000 ppi.

A light-receiving element included in the display device according to one embodiment of the present invention has a function of an optical sensor. Thus, the display device according to one embodiment of the present invention can display an image by the light-emitting element and can detect, for example, an object that is in contact with or approaches the display portion by the light-receiving element. In addition, the display device according to one embodiment of the present invention can perform authentication based on the fingerprint of a finger of a user of the display device in the case where the finger is in contact with the display portion, for example.

Providing the light-receiving element in the display portion eliminates the need for attachment of an external sensor to the display device. Thus, the number of components in the display device can be reduced, so that the display device can be made smaller and lightweight.

In addition, in the display device according to one embodiment of the present invention, the light-receiving element can detect light that is emitted from the light-emitting element to be delivered on an object and is reflected by the object. Thus, for example, even in a dark place, the object that is in contact with or approaches the display portion can be detected, and authentication such as fingerprint authentication can be performed.

In this specification and the like, a device manufactured using a metal mask or an FMM (a fine metal mask or a high-resolution metal mask) is sometimes referred to as a device having an MM (metal mask) structure. In addition, in this specification and the like, a device manufactured without using a metal mask or an FMM is sometimes referred to as a device having an MML (metal maskless) structure.

Note that in this specification and the like, a structure in which light-emitting layers in light-emitting elements of respective colors (here, blue (B), green (G), and red (R)) are separately formed or the light-emitting layers are separately patterned is sometimes referred to as an SBS (Side By Side) structure. In addition, in this specification and the like, a light-emitting element capable of emitting white light is sometimes referred to as a white light-emitting element. Note that a combination of a white light-emitting element with a coloring layer (e.g., a color filter) enables a full-color light-emitting element.

In addition, light-emitting elements can be roughly classified into a single structure and a tandem structure. A device having a single structure includes one light-emitting unit between a pair of electrodes, and the light-emitting unit preferably includes one or more light-emitting layers. To obtain white light emission, two or more light-emitting layers are selected so that emission colors of the light-emitting layers have a relationship of complementary colors. For example, when an emission color of a first light-emitting layer and an emission color of a second light-emitting layer have a relationship of complementary colors, it is possible to obtain a structure where the light-emitting element can emit white light as a whole. The same applies to a light-emitting element including three or more light-emitting layers.

A device having a tandem structure includes two or more light-emitting units between a pair of electrodes, and each light-emitting unit preferably includes one or more light-emitting layers. To obtain white light emission, the structure is made so that light from light-emitting layers of the light-emitting units can be combined to be white light. Note that a structure for obtaining white light emission is similar to that in the single structure. Note that in the device having the tandem structure, an intermediate layer such as a charge-generation layer is suitably provided between the plurality of light-emitting units.

Furthermore, when the above white light-emitting element (the single structure or the tandem structure) and a light-emitting element having an SBS structure are compared, the light-emitting element having the SBS structure can have lower power consumption than the white light-emitting element. Thus, in the case where the power consumption of the display device is required to be low, the light-emitting element having the SBS structure is suitably used. Meanwhile, in the white light-emitting element, manufacturing cost can be reduced or manufacturing yield can be increased because the manufacturing process of the white light-emitting element is simpler than that of the light-emitting element having the SBS structure.

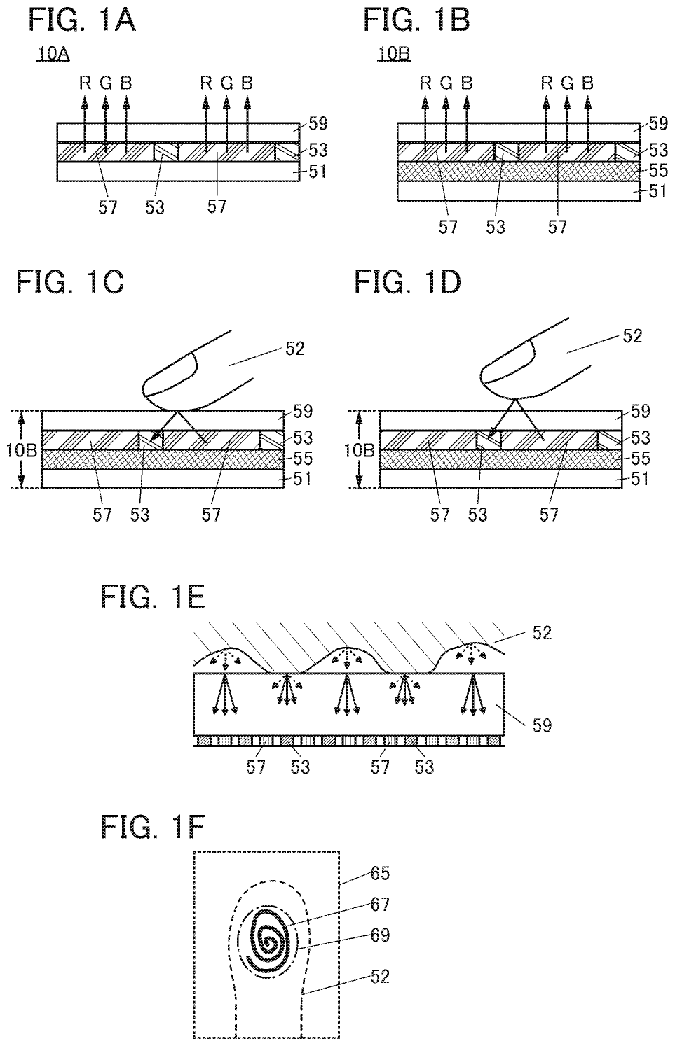

FIG. 1A to FIG. 1E are cross-sectional views illustrating structure examples of the display device according to one embodiment of the present invention.

A display device 10A illustrated in FIG. 1A includes layers 53 each including a light-receiving element and layers 57 each including a light-emitting element between a substrate 51 and a substrate 59.

A display device 10B illustrated in FIG. 1B includes a layer 55 including transistors, the layers 53 each including a light-receiving element, and the layers 57 each including a light-emitting element between the substrate 51 and the substrate 59.

In the display device 10A and the display device 10B, red (R) light, green (G) light, and blue (B) light are emitted from the layers 57 each including a light-emitting element.

In the display device according to one embodiment of the present invention, the plurality of pixels arranged in a matrix are provided in the display portion. One pixel includes one or more subpixels. One subpixel includes one light-emitting element or one light-receiving element. Four subpixels can be included in a pixel, for example. Specifically, for example, one pixel can include light-emitting elements of three colors of R, G, and B and a light-receiving element, or one pixel can include light-emitting elements of three colors of yellow (Y), cyan (C), and magenta (M) and a light-receiving element. Alternatively, five subpixels can be included in a pixel. Specifically, for example, one pixel can include light-emitting elements of four colors of R, G, B, and white (W) and a light-receiving element. Alternatively, one pixel can include light-emitting elements of four colors of R, G, B, and infrared (IR) and a light-receiving element. Note that the light-receiving element may be provided in all the pixels or may be provided in some of the pixels. In addition, one pixel may include a plurality of light-receiving elements.

The display device according to one embodiment of the present invention may have a function of detecting an object such as a finger that is in contact with the display device. For example, light emitted from the light-emitting element in the layer 57 including the light-emitting element is reflected by a finger 52 that touches the display device 10B as illustrated in FIG. 1C and FIG. 1D, and the light-receiving element in the layer 53 including the light-receiving element detects the reflected light. Thus, the touch of the finger 52 on the display device 10B can be detected in the case illustrated in FIG. 1C. In addition, the approach of the finger 52 on the display device 10B can be detected in the case illustrated in FIG. 1D. In other words, the display device according to one embodiment of the present invention can have a function of a touch sensor (also referred to as a direct touch sensor) or can have a function of a near touch sensor (also referred to as a hover sensor, a hover touch sensor, a contactless sensor, or a touchless sensor).

As described above, for example, in the case where the display device 10B has a function of a near touch sensor, even when the finger 52 does not touch the display device 10B, the finger 52 can be detected when the finger 52 approaches the display device 10B. For example, a structure is preferable in which the display device 10B can detect the finger 52 when a distance between the display device 10B and the finger 52 is more than or equal to 0.1 mm and less than or equal to 300 mm, preferably more than or equal to 3 mm and less than or equal to 50 mm. With this structure, the display device 10B can be operated without a direct touch of the finger 52 on the display device 10B. In other words, the display device 10B can be operated in a contactless (touchless) manner. With the above structure, the display device 10B can have a reduced risk of being dirty or damaged. Furthermore, the display device 10B can be operated with the finger 52 without dirt (e.g., dust, a virus, or the like) that might be attached to the display device 10B directly touching the finger 52.

In addition, the display device according to one embodiment of the present invention can have a function of detecting the fingerprint of the finger 52, for example. FIG. 1E schematically illustrates an enlarged view of a contact portion in a state where the finger 52 touches the substrate 59. Furthermore, FIG. 1E illustrates a state where the layers 57 each including a light-emitting element and the layers 53 each including a light-receiving element are alternately arranged.

The fingerprint of the finger 52 is formed of depressions and projections. Therefore, as illustrated in FIG. 1E, the projections of the fingerprint touch the substrate 59.

Reflection of light from a surface or an interface is categorized into regular reflection and diffuse reflection. Regularly reflected light is highly directional light with an angle of reflection equal to the angle of incidence. Diffusely reflected light has low directionality and low angular dependence of intensity. As for regular reflection and diffuse reflection, diffuse reflection components are dominant in the light reflected from the surface of the finger 52. Meanwhile, regular reflection components are dominant in the light reflected from the interface between the substrate 59 and the air.

The intensity of light that is reflected on a contact surface or a non-contact surface between the finger 52 and the substrate 59 and is incident on the layer 53 positioned directly below the contact surface or the non-contact surface is the sum of intensities of regularly reflected light and diffusely reflected light. As described above, regularly reflected light (indicated by solid arrows) is dominant in the depressions of the finger 52 where the finger 52 does not touch the substrate 59, whereas diffusely reflected light (indicated by dashed arrows) from the finger 52 is dominant in the projections where the finger 52 touches the substrate 59. Thus, the intensity of light received by the light-receiving element of the layer 53 positioned directly below the depression is higher than the intensity of light received by the light-receiving element of the layer 53 positioned directly below the projection. Accordingly, an image of the fingerprint of the finger 52 can be captured using the light-receiving element.

In the case where an arrangement interval between the light-receiving elements of the layers 53 is smaller than a distance between two projections of a fingerprint, preferably a distance between a depression and a projection adjacent to each other, a clear fingerprint image can be obtained. A distance between a depression and a projection of a human's fingerprint is generally within a range from 150 μm to 250 μm; thus, the arrangement interval between the light-receiving elements is, for example, less than or equal to 400 μm, preferably less than or equal to 200 μm, further preferably less than or equal to 150 μm, still further preferably less than or equal to 120 μm, yet further preferably less than or equal to 100 μm, yet still further preferably less than or equal to 50 μm. The arrangement interval is preferably as small as possible, and can be more than or equal to 1 μm, more than or equal to 10 μm, or more than or equal to 20 μm, for example.

FIG. 1F is an example of a fingerprint image captured by the display device according to one embodiment of the present invention. In FIG. 1F, the outline of the finger 52 is indicated by a dashed line and the outline of a contact portion 69 is indicated by a dashed-dotted line in a region 65. In the region 65, a high-contrast image of a fingerprint 67 can be captured owing to a difference in the amount of light incident on the light-receiving elements.

As described above, in the display device according to one embodiment of the present invention, the light-receiving element can detect light that is emitted from the light-emitting element to be delivered on the object such as the finger 52 and is reflected by the object such as the finger 52. Thus, for example, even in a dark place, the object that is in contact with or approaches the display portion, for example, can be detected, and authentication such as fingerprint authentication can be performed

In addition, providing the light-receiving element in the display portion eliminates the need for attachment of an external sensor to the display device. Thus, the number of components in the display device can be reduced, so that the display device can be made smaller and lightweight.

### Structure Example 1

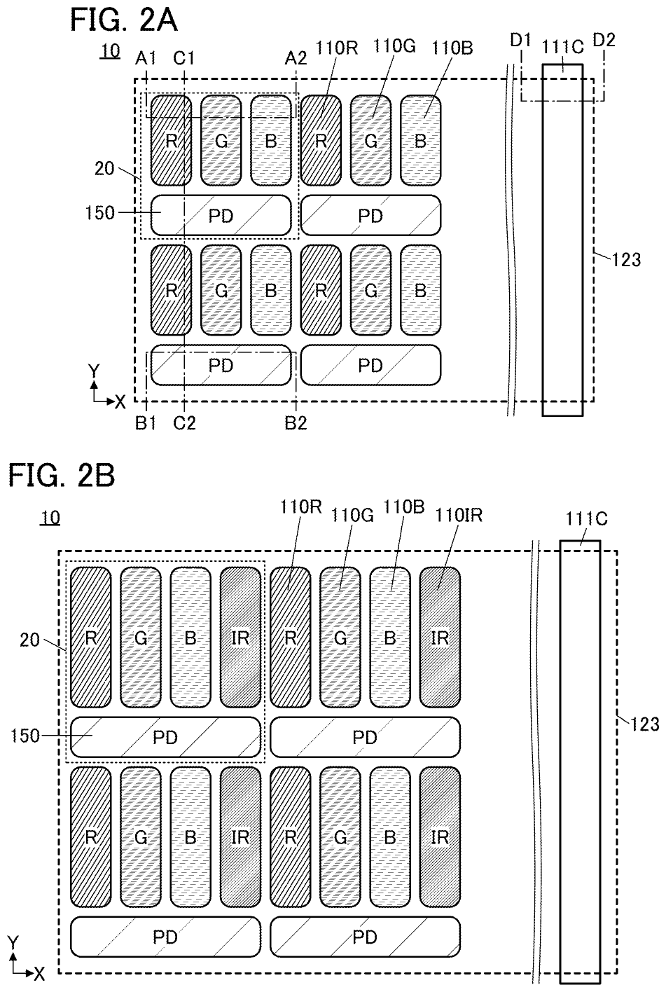

FIG. 2A is a schematic top view illustrating a structure example of the display device 10 of one embodiment of the present invention. The display device 10 includes a plurality of light-emitting elements 110R that emit red light, a plurality of light-emitting elements 110G that emit green light, a plurality of light-emitting elements 110B that emit blue light, and a plurality of light-receiving elements 150. In FIG. 2A, light-emitting regions of the light-emitting elements 110 are denoted by R, G, and B to easily differentiate the light-emitting elements 110. In addition, light-receiving regions of the light-receiving elements 150 are denoted by PD.

In this specification and the like, in the case where a common matter between the display device 10A and the display device 10B is described or in the case where it is not necessary to differentiate between these, for example, the display device 10A and the display device 10B are simply referred to as a “display device 10.” That is, the structure and the like of the display device 10 can be applied to both the display device 10A illustrated in FIG. 1A and the display device 10B illustrated in FIG. 1B. The same applies to other elements.

The light-emitting elements 110R, the light-emitting elements 110G, the light-emitting elements 110B, and the light-receiving elements 150 are arranged in a matrix. FIG. 2A illustrates an example where the light-emitting elements 110R, the light-emitting elements 110G, and the light-emitting elements 110B are arranged in an X direction and the light-receiving elements 150 are arranged thereunder. FIG. 2A also illustrates a structure example where the light-emitting elements 110 that emit light of the same color are arranged in a Y direction intersecting the X direction. In the display device 10 illustrated in FIG. 2A, a pixel 20 can be composed of a subpixel including the light-emitting element 110R, a subpixel including the light-emitting element 110G, and a subpixel including the light-emitting element 110B, which are arranged in the X direction, and a subpixel including the light-receiving element 150 provided under the subpixels, for example.

As the light-emitting elements 110R, the light-emitting elements 110G, and the light-emitting element 110B, EL elements such as OLEDs (Organic Light Emitting Diodes) or QLEDs (Quantum-dot Light Emitting Diodes) are preferably used. As a light-emitting substance contained in the EL element, a substance that emits fluorescence (a fluorescent material), a substance that emits phosphorescence (a phosphorescent material), an inorganic compound (e.g., a quantum dot material), a substance that exhibits thermally activated delayed fluorescence (a thermally activated delayed fluorescent (TADF) material), or the like can be given.

As the light-receiving element 150, a pn or pin photodiode can be used, for example. The light-receiving element 150 functions as a photoelectric conversion device that detects light incident on the light-receiving element 150 and generates electric charge. The amount of generated electric charge depends on the amount of incident light.

It is particularly preferable to use an organic photodiode including a layer containing an organic compound as the light-receiving element 150. An organic photodiode, which is easily made thin, lightweight, and large in area and has a high degree of freedom for shape and design, can be used in a variety of display devices.

In one embodiment of the present invention, an organic EL device is used as the light-emitting element 110, and an organic photodiode is used as the light-receiving element 150. The organic EL device and the organic photodiode can be formed over the same substrate. Thus, the organic photodiode can be incorporated in the display device including the organic EL device.

FIG. 2A illustrates a common electrode 123 and a connection electrode 111C. Here, the connection electrode 111C is electrically connected to the common electrode 123. The connection electrode 111C is provided outside a display portion where the light-emitting element 110 and the light-receiving element 150 are arranged. In FIG. 2A, the common electrode 123 having a region overlapped with the light-emitting element 110, the light-receiving element 150, and the connection electrode 111C is shown by dashed lines.

The connection electrode 111C can be provided along the outer periphery of the display portion. For example, the connection electrode 111C may be provided along one side of the outer periphery of the display portion or may be provided across two or more sides of the outer periphery of the display portion. That is, when the display portion has a rectangular top surface, the top surface of the connection electrode 111C can have a band shape, an L shape, a square bracket shape, a frame-like shape, or the like.

FIG. 2B is a schematic top view illustrating a structure example of the display device 10 and is a modification example of the display device 10 illustrated in FIG. 2A. The display device 10 illustrated in FIG. 2B differs from the display device 10 illustrated in FIG. 2A in that light-emitting elements 110IR that emit infrared light are included. The light-emitting elements 110IR can emit near-infrared light (light with a wavelength of greater than or equal to 750 nm and less than or equal to 1300 nm), for example.

In the example illustrated in FIG. 2B, the light-emitting elements 110IR as well as the light-emitting elements 110R, the light-emitting elements 110G, and the light-emitting elements 110B are arranged in the X direction, and the light-receiving elements 150 are arranged thereunder. In addition, the light-receiving elements 150 have a function of detecting infrared light.

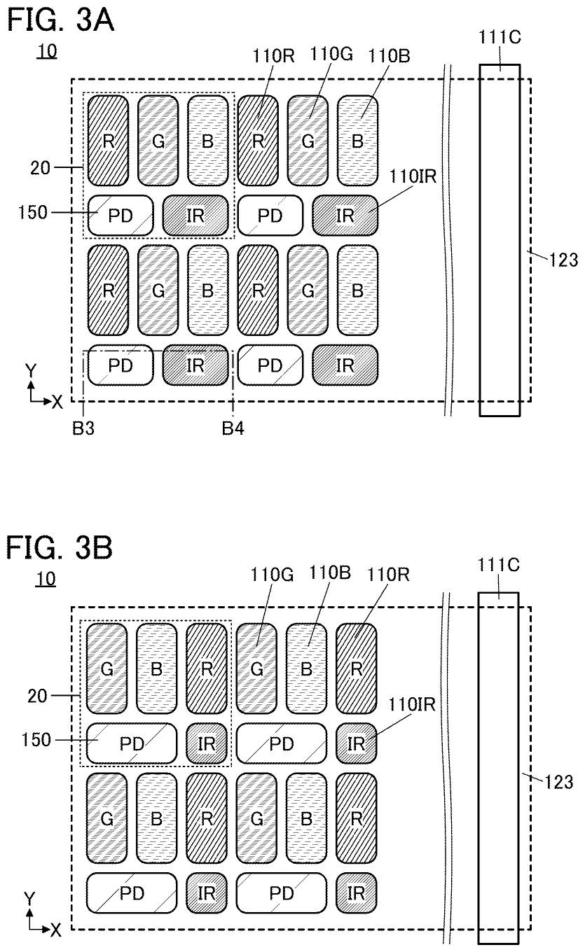

FIG. 3A is a schematic top view illustrating a structure example of the display device 10 and is a modification example of the display device 10 illustrated in FIG. 2B. The display device 10 illustrated in FIG. 3A differs from the display device 10 illustrated in FIG. 2B in that the light-receiving elements 150 and the light-emitting elements 110IR are alternately arranged in the X direction.

In the display device 10 illustrated in FIG. 3A, the light-emitting element 110R, the light-emitting element 110G, and the light-emitting element 110B are arranged in a row different from the row of the light-emitting element 110IR. Thus, the light-emitting element 110R, the light-emitting element 110G, and the light-emitting element 110B can have larger widths (larger lengths in the X direction), so that the luminance of light emitted from the pixel 20 can be increased.

FIG. 3B is a schematic top view illustrating a structure example of the display device 10 and is a modification example of the display device 10 illustrated in FIG. 3A. The display device 10 illustrated in FIG. 3A differs from the display device 10 illustrated in FIG. 3A in that the light-emitting elements 110 are arranged in the X direction in the order of G, B, and R instead of the order of R, G, and B. The display device 10 illustrated in FIG. 3B differs from the display device 10 illustrated in FIG. 3A also in that the light-receiving element 150 is provided below the light-emitting element 110G and the light-emitting element 110B and the light-emitting element 110IR is provided below the light-emitting element 110R.

The area occupied by the light-receiving element 150 in the display device 10 illustrated in FIG. 3B is larger than the area occupied by the light-receiving element 150 in the display device 10 illustrated in FIG. 3A. Accordingly, the light detection sensitivity of the light-receiving element 150 can be increased. Therefore, for example, in the case where the display device 10 has a function of a touch sensor or a near touch sensor, an object that is in contact with or approaches the display device 10 can be detected with high accuracy. In particular, in the case where the display device 10 has a function of a near touch sensor, the light detection accuracy of the light-receiving element 150 has great influence on the detection accuracy of the object; thus, the area occupied by the light-receiving element 150 is preferably made large.

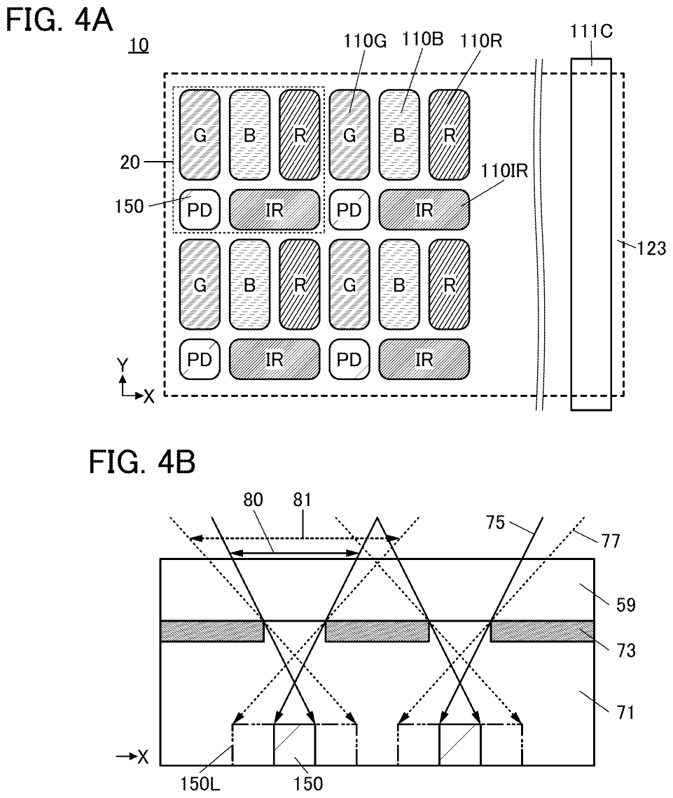

FIG. 4A is a schematic top view illustrating a structure example of the display device 10 and is a modification example of the display device 10 illustrated in FIG. 3B. The display device illustrated in FIG. 4A differs from the display device 10 illustrated in FIG. 3B in that the light-receiving element 150 is provided below the light-emitting element 110G and the light-emitting element 110IR is provided below the light-emitting element 110B and the light-emitting element 110R.

The area occupied by the light-receiving element 150 in the display device 10 illustrated in FIG. 4A is smaller than the area occupied by the light-receiving element 150 in the display device 10 illustrated in FIG. 3B. When the area occupied by the light-receiving element 150 is made small, the light-receiving range of each light-receiving element 150 can be narrowed. It is thus possible to reduce overlap between the light-receiving ranges of different light-receiving elements 150, e.g., adjacent light-receiving elements 150. This can inhibit blurring in an image captured using the light-receiving element 150 and failure in clear image capturing. Accordingly, for example, in the case where the display device 10 has a function of performing authentication such as fingerprint authentication, the area occupied by the light-receiving element 150 is preferably reduced because a clear fingerprint image can be captured, for example, which leads to higher authentication accuracy.

FIG. 4B is a cross-sectional view illustrating changes in the light-receiving range of the light-receiving element 150 when the area occupied by the light-receiving element 150, specifically, the length of the light-receiving element 150 in the X direction is changed. FIG. 4B illustrates the light-receiving element 150 on the bottom surface side of a layer 71 and a light-blocking layer 73 on the top surface side of the layer 71. FIG. 4B also illustrates the substrate 59 over the layer 71. In addition, a light-receiving element whose length in the X direction is made approximately three times as large as that of the light-receiving element 150 is referred to as a light-receiving element 150L.

In FIG. 4B, light that is incident on the light-receiving elements 150 is referred to as light 75 and is indicated by solid lines. In addition, light that is not incident on the light-receiving elements 150 but is incident on the light-receiving elements 150L is referred to as light 77 and is indicated by broken lines. Furthermore, the light-receiving range of each light-receiving element 150 is referred to as a light-receiving range 80, and the light-receiving range of each light-receiving element 150L is referred to as a light-receiving range 81.

As illustrated in FIG. 4B, the light-receiving range 80 of the light-receiving element 150 is narrower than the light-receiving range 81 of the light-receiving element 150L. That is, when the area occupied by the light-receiving element is made small, the light-receiving range of each light-receiving element is narrowed, which reduces overlap of the light-receiving ranges between different light-receiving elements. FIG. 4B illustrates an example where the light-receiving ranges 80 between adjacent light-receiving elements 150 are not overlapped with each other on a surface of the substrate 59 but some of the light-receiving ranges 81 between adjacent light-receiving elements 150L are partly overlapped with each other.

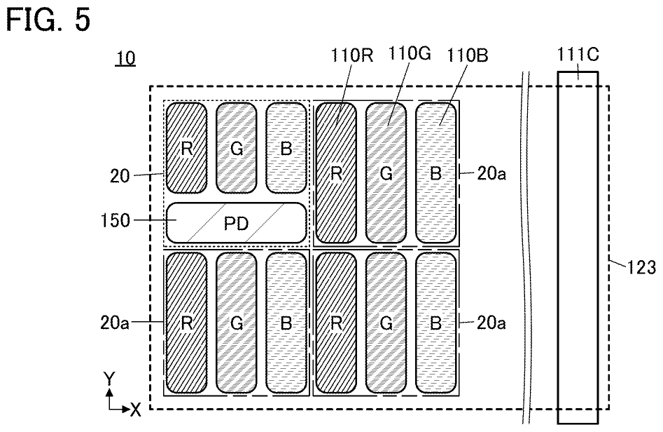

FIG. 5 is a schematic top view illustrating a structure example of the display device 10 and is a modification example of the display device 10 illustrated in FIG. 2A. The display device 10 illustrated in FIG. 5 differs from the display device 10 illustrated in FIG. 2A in that only part of the pixels 20 is provided with the light-receiving element 150. Note that in FIG. 5, a pixel 20a is the pixel 20 that is not provided with the light-receiving element 150.

When the display device 10 has the structure illustrated in FIG. 5, the drive frequency of the display device 10 can be increased. Thus, for example, in the case where the display device 10 has a function of a touch sensor or a near touch sensor, the position of an object that is in contact with or approaches the display device 10 can be detected quickly. Accordingly, for example, the movement of the object that is in contact with or approaches the display device 10 can be detected at high speed and with high accuracy.

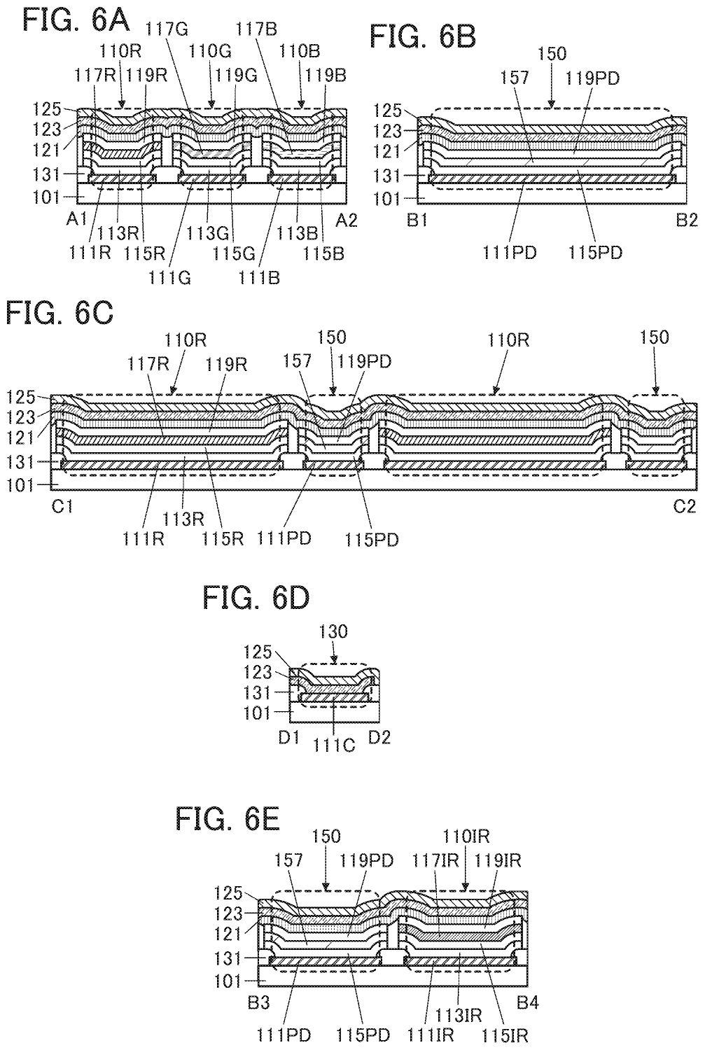

FIG. 6A is a cross-sectional view taken along dashed-dotted line A1-A2 in FIG. 2A, and FIG. 6B is a cross-sectional view taken along dashed-dotted line B1-B2 in FIG. 2A. In addition, FIG. 6C is a cross-sectional view taken along dashed-dotted line C1-C2 in FIG. 2A, and FIG. 6D is a cross-sectional view taken along dashed-dotted line D1-D2 in FIG. 2A. Furthermore, FIG. 6E is a cross-sectional view taken along dashed-dotted line B3-B4 in FIG. 3A. The light-emitting element 110R, the light-emitting element 110G, the light-emitting element 110B, and the light-receiving element 150 are provided over a substrate 101. In addition, in the case where the display device 10 includes the light-emitting element 110IR, the light-emitting element 110IR is provided over the substrate 101.

In the case where the expression “B over A” or “B under A” is used in this specification and the like, for example, A and B do not always need to include a region where they are in contact with each other.

FIG. 6A illustrates a cross-sectional structure example of the light-emitting element 110R, the light-emitting element 110G, and the light-emitting element 110B. In addition, FIG. 6B illustrates a cross-sectional structure example of the light-receiving element 150.

The light-emitting element 110R includes a pixel electrode 111R, a hole-injection layer 113R, a hole-transport layer 115R, a light-emitting layer 117R, an electron-transport layer 119R, the common layer 121, and the common electrode 123. The light-emitting element 110G includes a pixel electrode 111G, a hole-injection layer 113G, a hole-transport layer 115G, a light-emitting layer 117G, an electron-transport layer 119G, the common layer 121, and the common electrode 123. The light-emitting element 110B includes a pixel electrode 111B, a hole-injection layer 113B, a hole-transport layer 115B, a light-emitting layer 117B, an electron-transport layer 119B, the common layer 121, and the common electrode 123. The light-receiving element 150 includes a pixel electrode 111PD, a hole-transport layer 115PD, a light-receiving layer 157, an electron-transport layer 119PD, the common layer 121, and the common electrode 123.

The common layer 121 has a function of an electron-injection layer in the light-emitting element 110. Meanwhile, the common layer 121 has a function of an electron-transport layer in the light-receiving element 150. Thus, the light-receiving element 150 does not necessarily include the electron-transport layer 119PD.

The hole-injection layer 113, the hole-transport layer 115, the electron-transport layer 119, and the common layer 121 can also be referred to as functional layers.

The pixel electrode 111, the hole-injection layer 113, the hole-transport layer 115, the light-emitting layer 117, and the electron-transport layer 119 can each be separately provided for each element. The common layer 121 and the common electrode 123 are shared by the light-emitting element 110R, the light-emitting element 110G, the light-emitting element 110B, and the light-receiving element 150.

The light-emitting element 110 and the light-receiving element 150 may each include a hole-blocking layer and an electron-blocking layer other than the layers illustrated in FIG. 6A and FIG. 6B. The light-emitting element 110 and the light-receiving element 150 may each include a layer containing, a substance with a bipolar property (a substance with a high electron-transport property and a high hole-transport property).

A gap is provided between the common layer 121 and an insulating layer 131. Accordingly, it is possible to inhibit the common layer 121 from being in contact with the side surface of the light-emitting layer 117, the side surface of the light-receiving layer 157, the side surface of the hole-transport layer 115, and the side surface of the hole-injection layer 113. Thus, short-circuit in the light-emitting element 110 and short-circuit in the light-receiving element 150 can be inhibited.

The shorter the distance between the light-emitting layers 117 is, the more easily the gap is formed, for example. For example, when the distance between the light-emitting units 512 is less than or equal to 1 μm, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm, the gap can be suitably formed.

In FIG. 6A, the light-emitting element 110 includes the pixel electrode 111, the hole-injection layer 113, the hole-transport layer 115, the light-emitting layer 117, the electron-transport layer 119, the common layer 121 (electron-injection layer), and the common electrode 123 in this order from the bottom, and the light-receiving element 150 includes the pixel electrode 111PD, the hole-transport layer 115PD, the light-receiving layer 157, the electron-transport layer 119PD, the common layer 121, and the common electrode 123 in this order from the bottom; however, one embodiment of the present invention is not limited thereto. For example, the light-emitting element 110 may include a pixel electrode, an electron-injection layer, an electron-transport layer, a light-emitting layer, a hole-transport layer, a hole-injection layer, and a common electrode in this order from the bottom, and the light-receiving element 150 may include a pixel electrode, an electron-transport layer, a light-receiving layer, a hole-transport layer, and a common electrode in this order from the bottom. In that case, the hole-injection layer included in the light-emitting element 110 can be a common layer, and the common layer can be provided between the hole-transport layer included in the light-receiving element 150 and the common electrode. In addition, the electron-injection layers can be separated between the light-emitting elements 110.

Although the electron-transport layer is considered as being provided over the hole-transport layer in the description below, the following description can also be applied to the case where the electron-transport layer is provided under the hole-transport layer, when “electron” is replaced with “hole” and “hole” is replaced with “electron”, for example.

The hole-injection layer is a layer injecting holes from an anode to the hole-transport layer, and a layer containing a material with a high hole-injection property. Examples of the material with a high hole-injection property include an aromatic amine compound, a composite material containing a hole-transport material and an acceptor material (an electron-accepting material), and the like.

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, a material having a high hole-transport property, such as a π-electron rich heteroaromatic compound (e.g., a carbazole derivative, a thiophene derivative, a furan derivative, or the like) or an aromatic amine (a compound having an aromatic amine skeleton), is preferable.

The electron-transport layer is a layer transporting electrons, which are injected from a cathode by the electron-injection layer, to the light-emitting layer. The electron-transport layer is a layer containing an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-injection layer is a layer injecting electrons from a cathode to the electron-transport layer and a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

For the electron-injection layer, it is possible to use, for example, an alkali metal, an alkaline earth metal, or a compound thereof, such as lithium, cesium, lithium fluoride (LiF), cesium fluoride (CsF), calcium fluoride (CaF₂), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOx), or cesium carbonate.

Alternatively, an electron-transport material may be used for the electron-injection layer. For example, a compound having an unshared electron pair and an electron deficient heteroaromatic ring can be used for the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In addition, in general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-bis(naphthalen-2-yl)-4,7-diphenyl-1,10-phenanthroline (abbreviation: NBPhen), diquinoxalino[2,3-a:2′,3′-c]phenazine (abbreviation:HATNA),2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

The light-emitting layer is a layer containing a light-emitting substance. The light-emitting layer can include one or more kinds of light-emitting substances. As the light-emitting substance, a substance that emits light of blue, purple, bluish purple, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, a quantum dot material, and the like.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, a naphthalene derivative, and the like.

Examples of the phosphorescent material include an organometallic complex (in particular, an iridium complex) having a 4H-triazole skeleton, a 1H-triazole skeleton, an imidazole skeleton, a pyrimidine skeleton, a pyrazine skeleton, or a pyridine skeleton; an organometallic complex (in particular, an iridium complex) having a phenylpyridine derivative including an electron-withdrawing group as a ligand; a platinum complex; a rare earth metal complex; and the like.

The light-emitting layer may contain one or more kinds of organic compounds (a host material, an assist material, and the like) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that emits light whose wavelength is to be overlapped with the wavelength of the lowest-energy-side absorption band of the light-emitting substance, energy can be transferred smoothly and light emission can be obtained efficiently. With this structure, the high efficiency, low-voltage driving, and long lifetime of the light-emitting element can be achieved at the same time.

The light-emitting layer 117R included in the light-emitting element 110R contains at least a light-emitting organic compound that emits light with intensity in the red wavelength range. The light-emitting layer 117G included in the light-emitting element 110G contains at least a light-emitting organic compound that emits light with intensity in the green wavelength range. The light-emitting layer 117B included in the light-emitting element 110B contains at least a light-emitting organic compound that emits light with intensity in the blue wavelength range. The light-receiving layer 157 included in the light-receiving element 150 contains an organic compound having detection sensitivity in a wavelength range of visible light, for example.

A conductive film with a property of transmitting visible light is used for either one of the pixel electrode 111 and the common electrode 123, and a conductive film with a property of reflecting visible light is used for the other. When the pixel electrode 111 has a light-transmitting property and the common electrode 123 has a light-reflecting property, the display device 10 can have a bottom emission structure. The display device 10 can have a top emission structure when the pixel electrode 111 has a light-reflecting property and the common electrode 123 has a light-transmitting property. Note that when both the pixel electrode 111 and the common electrode 123 have a light-transmitting property, the display device 10 can have a dual emission structure.

The light-emitting element 110 preferably has a micro optical resonator (microcavity) structure. In that case, light emitted from the light-emitting layer 117 can be resonated between the pixel electrode 111 and the common electrode 123, so that light emitted from the light-emitting element 110 can be intensified.

In the case where the light-emitting element 110 has a microcavity structure, one of the common electrode 123 and the pixel electrode 111 is preferably an electrode having both a light-transmitting property and a light-reflecting property (a transflective electrode), and the other of the common electrode 123 and the pixel electrode 111 is preferably a reflective electrode. Here, the semi-transmissive and semi-reflective electrode can have a stacked-layer structure of a reflective electrode and an electrode having a property of transmitting visible light (also referred to as a transparent electrode). Note that the transparent electrode can be referred to as an optical adjustment layer.

The transparent electrode has a light transmittance higher than or equal to 40%. For example, an electrode having a visible light (light with a wavelength greater than or equal to 400 nm and less than 750 nm) transmittance higher than or equal to 40% is preferably used in the light-emitting element 110. The visible light reflectance of the transflective electrode is higher than or equal to 10% and lower than or equal to 95%, preferably higher than or equal to 30% and lower than or equal to 80%. The reflective electrode has a visible light reflectance of higher than or equal to 40% and lower than or equal to 100%, preferably higher than or equal to 70% and lower than or equal to 100%. These electrodes preferably have a resistivity lower than or equal to 1×10⁻² Ωcm. Note that in the case where a light-emitting element that emits near-infrared light is used in the display device, the near-infrared light (light at wavelengths greater than or equal to 750 nm and less than or equal to 1300 nm) transmittance and reflectance of these electrodes are preferably in the above numeral ranges.

The insulating layer 131 is provided to cover end portions of the pixel electrode 111R, end portions of the pixel electrode 111G, end portions of the pixel electrode 111B, and end portions of the pixel electrode 111PD. End portions of the insulating layer 131 preferably have a tapered shape. Note that the insulating layer 131 is not necessarily provided when not needed.

For example, the hole-injection layer 113R, the hole-injection layer 113G, the hole-injection layer 113B, and the hole-transport layer 115PD each include a region that is in contact with a top surface of the pixel electrode 111 and a region that is in contact with a surface of the insulating layer 131. In addition, end portions of the hole-injection layer 113R, end portions of the hole-injection layer 113G, end portions of the hole-injection layer 113B, and end portions of the hole-transport layer 115PD are positioned over the insulating layer 131.

As illustrated in FIG. 6A, a gap is provided between the light-emitting elements 110 that emit light of different colors, for example, between two light-emitting layers 117. In this manner, for example, the light-emitting layer 117R, the light-emitting layer 117G, and the light-emitting layer 117B are preferably provided not to be in contact with one another. This suitably prevents unintentional light emission due to current flowing through two adjacent light-emitting layers 117. Thus, the contrast of the display device 10 can be increased, so that the display quality of the display device 10 can be increased.

A protective layer 125 is provided over the common electrode 123. The protective layer 125 has a function of preventing diffusion of impurities such as water into the light-emitting elements from above.

The protective layer 125 can have, for example, a single-layer structure or a stacked-layer structure at least including an inorganic insulating film. As the inorganic insulating film, for example, an oxide film and a nitride film, such as a silicon oxide film, a silicon oxynitride film, a silicon nitride oxide film, a silicon nitride film, an aluminum oxide film, an aluminum oxynitride film, and a hafnium oxide film can be given. Alternatively, a semiconductor material such as indium gallium oxide or indium gallium zinc oxide may be used for the protective layer 125.

In this specification and the like, a silicon oxynitride film refers to a film in which oxygen content is higher than nitrogen content in its composition. In addition, a silicon nitride oxide film refers to a film in which nitrogen content is higher than oxygen content in its composition.

Alternatively, a stacked-layer film of an inorganic insulating film and an organic insulating film can be used for the protective layer 125. For example, a structure in which an organic insulating film is sandwiched between a pair of inorganic insulating films is preferable. Furthermore, the organic insulating film preferably functions as a planarization film. This enables a top surface of the organic insulating film to be flat, and accordingly, coverage with the inorganic insulating film thereover is improved, which leads to an improvement in barrier properties. Moreover, a top surface of the protective layer 125 is flat, which is preferable because the influence of an uneven shape due to a lower structure can be reduced in the case where a component (e.g., a color filter, an electrode of a touch sensor, a lens array, or the like) is provided above the protective layer 125.

FIG. 6C illustrates a cross-sectional structure example of the display device 10 in the Y direction, specifically, a cross-sectional structure example of the light-emitting element 110R and the light-receiving element 150. Note that the light-emitting element 110G and the light-emitting element 110B can be arranged in the Y direction like the light-emitting element 110R.

FIG. 6D illustrates a connection portion 130 where the connection electrode 111C and the common electrode 123 are electrically connected to each other. In the connection portion 130, the common electrode 123 is provided on and in contact with the connection electrode 111C and the protective layer 125 is provided to cover the common electrode 123. In addition, the insulating layer 131 is provided to cover end portions of the connection electrode 111C.

FIG. 6E illustrates a cross-sectional structure example of the light-emitting element 110IR in addition to the cross-sectional structure example of the light-receiving element 150. The light-emitting element 110IR includes a pixel electrode 111 IR, a hole-injection layer 11318, a hole-transport layer 1151R, a light-emitting layer 1171R, an electron-transport layer 1191R, the common layer 121, and the common electrode 123.

The light-emitting layer 117IR included in the light-emitting element 110IR contains at least a light-emitting organic compound that emits light having intensity in an infrared light wavelength range. For example, the light-emitting layer 1171R contains a light-emitting organic compound that emits light having intensity in a near infrared light wavelength range. In the case where the display device 10 includes the light-emitting element 110IR, the light-receiving layer 157 included in the light-receiving element 150 contains, for example, an organic compound that has detection accuracy in an infrared light (e.g., near infrared light) wavelength range.

### Manufacturing Method Example

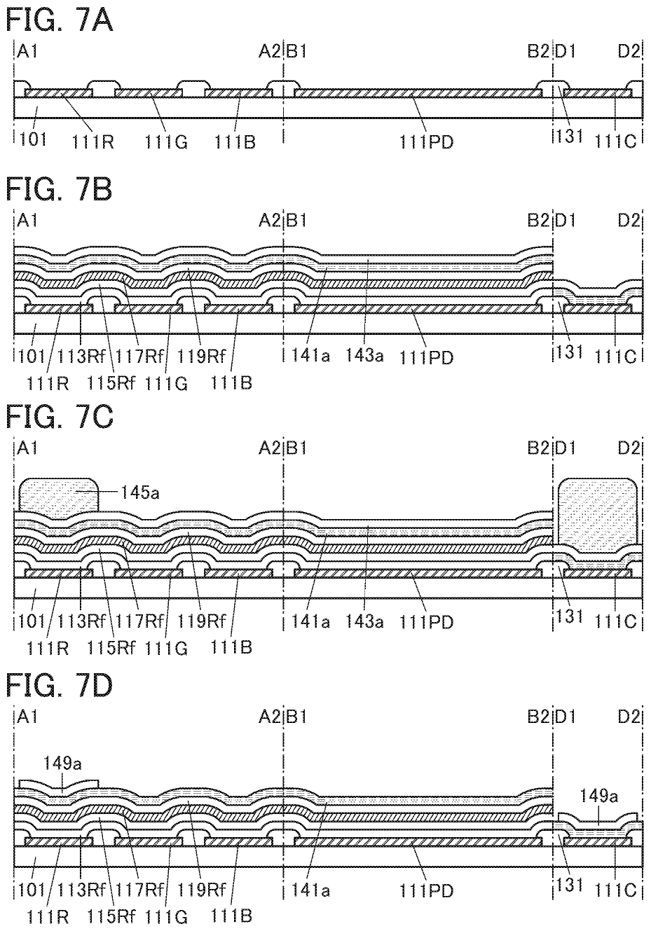

An example of a method for manufacturing the display device according to one embodiment of the present invention will be described below with reference to drawings. Here, a method for manufacturing the display device 10 illustrated in FIG. 2A and FIG. 6A to FIG. 6D is described as an example. FIG. 7A to FIG. 10C are schematic cross-sectional views in steps of the method for manufacturing the display device illustrated below. FIG. 7A to FIG. 10C illustrate cross sections corresponding to dashed-dotted line A1-A2, cross sections corresponding to dashed-dotted line B1-B2, and cross sections corresponding to dashed-dotted line D1-D2 in FIG. 2A.

Note that thin films that constitute the display device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD) method and a thermal CVD method. An example of a thermal CVD method is a metal organic CVD (MOCVD) method.

Alternatively, thin films included in the display device (insulating films, semiconductor films, conductive films, and the like) can be formed by a method such as spin coating, dipping, spray coating, ink-jetting, dispensing, screen printing, offset printing, a doctor knife method, slit coating, roll coating, curtain coating, or knife coating.

In addition, when the thin films included in the display device are processed, a photolithography method can be used, for example. Besides, the thin films may be processed by a nanoimprinting method, a sandblasting method, a lift-off method, or the like.

There are the following two typical examples of a photolithography method. In one of the methods, a resist mask is formed over a thin film that is to be processed, the thin film is processed by etching, and the resist mask is removed. In the other method, a photosensitive thin film is deposited and then processed into a desired shape by exposure and development.

For light used for exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet light, KrF laser light, ArF laser light, or the like can be used. In addition, exposure may be performed by liquid immersion exposure technique. Alternatively, for the light used for the exposure, extreme ultraviolet (EUV) light or X-rays may be used. Furthermore, instead of the light used for the exposure, an electron beam can also be used. It is preferable to use extreme ultraviolet light, X-rays, or an electron beam because extremely minute processing is possible. Note that when exposure is performed by scanning of a beam such as an electron beam, a photomask is unnecessary.

For etching of the thin films, a dry etching method, a wet etching method, a sandblasting method, or the like can be used.

In order to manufacture the display device 10, the substrate 101 is prepared first. As the substrate 101, a substrate having at least heat resistance high enough to withstand the following heat treatment can be used. In the case where an insulating substrate is used as the substrate 101, a glass substrate, a quartz substrate, a sapphire substrate, a ceramic substrate, an organic resin substrate, or the like can be given. Alternatively, it is possible to use a semiconductor substrate such as a single crystal semiconductor substrate or a polycrystalline semiconductor substrate including silicon, silicon carbide, or the like as a material; a compound semiconductor substrate of silicon germanium or the like; or an SOI substrate.

Then, the pixel electrode 111R, the pixel electrode 111G, the pixel electrode 111B, the pixel electrode 111PD, and the connection electrode 111C are formed over the substrate 101. First, a conductive film to be the pixel electrode is deposited, a resist mask is formed by a photolithography method, and an unnecessary portion of the conductive film is removed by etching. After that, the resist mask is removed, so that the pixel electrode 111R, the pixel electrode 111G, and the pixel electrode 111B can be formed.

In the case where a conductive film that has a property of reflecting visible light is used for the pixel electrode, it is preferable to employ a material having reflectance as high as possible in the entire wavelength range of visible light (e.g., silver, aluminum, or the like). This can increase color reproducibility as well as light extraction efficiency of the light-emitting elements.

Then, the insulating layer 131 is formed to cover the end portions of the pixel electrode 111R, the pixel electrode 111G, the pixel electrode 111B, and the pixel electrode 111PD (FIG. 7A). An organic insulating film or an inorganic insulating film can be used for the insulating layer 131. The end portions of the insulating layer 131 preferably have a tapered shape to improve step coverage with a film in a later step. In particular, when an organic insulating film is used, a photosensitive material is preferably used so that the shape of the end portions can be easily controlled by exposure and development conditions. Note that for the insulating layer 131, an inorganic insulating film may be used. Using an inorganic insulating film for the insulating layer 131 enables the display device 10 to have high resolution.

Subsequently, a functional film 113Rf to be the hole-injection layer 113R in a later step is formed over the pixel electrode 111R, the pixel electrode 111G, the pixel electrode 111B, the pixel electrode 111PD, and the insulating layer 131. After that, a functional film 115Rf to be the hole-transport layer 115R, a light-emitting film 117Rf to be the light-emitting layer 117R, and a functional film 119Rf to be the electron-transport layer 119R are sequentially formed over the functional film 113Rf. The functional film 113Rf, the functional film 115Rf, the light-emitting film 117Rf, and the functional film 119Rf can be formed by, for example, an evaporation method, a sputtering method, an inkjet method, or the like. Without limitation to this, the above deposition method can be used as appropriate.

The functional film 113Rf, the functional film 115Rf, the light-emitting film 117Rf, and the functional film 119Rf are preferably formed not to be provided over the connection electrode 111C. For example, in the case where the functional film 113Rf, the functional film 115Rf, the light-emitting film 117Rf, and the functional film 119Rf are formed by an evaporation method or a sputtering method, these films are preferably formed using a shielding mask so that the functional film 113Rf, the functional film 115Rf, the light-emitting film 117Rf, and the functional film 119Rf are not deposited over the connection electrode 111C.

Then, a sacrificial film 141a is deposited over the functional film 119Rf. Alternatively, the sacrificial film 141a can be provided in contact with the top surface of the connection electrode 111C.

As the sacrificial film 141a, it is possible to use a film that has high tolerance to etching processing of the functional film 119Rf, the light-emitting film 117Rf, the functional film 115Rf, and the functional film 113Rf, that is, a film having high etching selectivity. Alternatively, as the sacrificial film 141a, it is possible to use a film having high etching selectivity with respect to a protective film such as a protective film 143a described later. Alternatively, as the sacrificial film 141a, it is possible to use a film that can be removed by a wet etching method with which damage to the functional film 119Rf, the light-emitting film 117Rf, the functional film 115Rf, and the functional film 113Rf is small.

An inorganic film such as a metal film, an alloy film, a metal oxide film, a semiconductor film, or an inorganic insulating film can be used as the sacrificial film 141a, for example. The sacrificial film 141a can be formed by a variety of deposition methods such as a sputtering method, an evaporation method, a CVD method, and an ALD method.

For the sacrificial film 141a, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver.

Alternatively, for the sacrificial film 141a, a metal oxide such as an indium gallium zinc oxide (an In—Ga—Zn oxide, also referred to as IGZO) can be used. It is also possible to use indium oxide, an indium zinc oxide (an In—Zn oxide), an indium tin oxide (an In—Sn oxide), an indium titanium oxide (an In—Ti oxide), an indium tin zinc oxide (an In—Sn—Zn oxide), an indium titanium zinc oxide (an In—Ti—Zn oxide), an indium gallium tin zinc oxide (an In—Ga—Sn—Zn oxide), or the like. Alternatively, an indium tin oxide containing silicon can also be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium. In particular, M is preferably one or more selected from gallium, aluminum, and yttrium.

Alternatively, an inorganic insulating material such as aluminum oxide, hafnium oxide, or silicon oxide can be used for the sacrificial film 141a.

Alternatively, for the sacrificial film 141a, it is preferable to use a material that can be dissolved in a solvent chemically stable with respect to at least the functional film 119Rf. In particular, a material that is dissolved in water or alcohol can be suitably used for the sacrificial film 141a. In deposition of the sacrificial film 141a, it is preferable that application of such a material that has been dissolved in a solvent such as water or alcohol be performed by a wet deposition method and followed by heat treatment for evaporating the solvent. At this time, the heat treatment is preferably performed in a reduced-pressure atmosphere because the solvent can be removed at a low temperature in a short time and thermal damage to the functional film 119Rf, the light-emitting film 117Rf, the functional film 115Rf, and the functional film 113Rf can be reduced accordingly.

Examples of the wet deposition method that can be used for forming the sacrificial film 141a include spin coating, dipping, spray coating, ink-jetting, dispensing, screen printing, offset printing, a doctor knife method, slit coating, roll coating, curtain coating, knife coating, and the like.

For the sacrificial film 141a, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used.

Next, the protective film 143a is formed over the sacrificial film 141a (FIG. 7B).

The protective film 143a is a film used as a hard mask when the sacrificial film 141a is etched later. In addition, when the sacrificial film 143a is etched later, the sacrificial film 141a is exposed. Thus, a combination of films having high etching selectivity therebetween is selected for the sacrificial film 141a and the protective film 143a. It is thus possible to select a film that can be used for the protective film 143a depending on an etching condition of the sacrificial film 141a and an etching condition of the protective film 143a.

For example, in the case where dry etching using a gas containing fluorine (also referred to as a fluorine-based gas) is used for etching of the protective film 143a, silicon, silicon nitride, silicon oxide, tungsten, titanium, molybdenum, tantalum, tantalum nitride, an alloy containing molybdenum and niobium, an alloy containing molybdenum and tungsten, or the like can be used for the protective film 143a. Here, for example, a metal oxide film such as IGZO or ITO is given as a film having high etching selectivity (that is, enabling low etching rate) in dry etching using the fluorine-based gas, and such a film can be used as the sacrificial film 141a.

Note that without being limited to this, a material of the protective film 143a can be selected from a variety of materials depending on the etching condition of the sacrificial film 141a and the etching condition of the protective film 143a. For example, the material of the protective film 143a can be selected from the films that can be used as the sacrificial film 141a.

Alternatively, a nitride film can be used as the protective film 143a, for example. Specifically, it is also possible to use a film of a nitride such as silicon nitride, aluminum nitride, hafnium nitride, titanium nitride, tantalum nitride, tungsten nitride, gallium nitride, or germanium nitride.

Alternatively, an oxide film can be used as the protective film 143a. An oxide film or an oxynitride film of silicon oxide, silicon oxynitride, aluminum oxide, aluminum oxynitride, hafnium oxide, hafnium oxynitride, or the like can also be typically used.

As the protective film 143a, an organic film that can be used for the light-emitting film 117Rf, for example, may be used. The use of such an organic film is preferable, in which case the deposition apparatus for the light-emitting film 117Rf, for example, can be used in common.

Then, over the protective film 143a, a resist mask 145a is formed in each of a position overlapped with the pixel electrode 111R and a position overlapped with the connection electrode 111C (FIG. 7C).

For the resist mask 145a, a resist material containing a photosensitive resin, such as a positive type resist material or a negative type resist material can be used.

Here, in the case where the protective film 143a is not formed and the resist mask 145a is formed over the sacrificial film 141a, when a defect such as a pinhole exists in the sacrificial film 141a, there is a risk of dissolving the functional film 119Rf, for example, due to a solvent of the resist material. Such a defect can be prevented by using the protective film 143a.

Note that in the case where a film that is unlikely to cause a defect such as a pinhole is used as the sacrificial film 141a, the resist mask 145a may be formed directly on the sacrificial film 141a without using the protective film 143a.

Next, part of the protective film 143a that is not covered with the resist mask 145a is removed by etching, so that a protective layer 149a is formed. At this time, the protective layer 149a is concurrently formed also over the connection electrode 111C.

In the etching of the protective film 143a, an etching condition with high selectively is preferably used so that the sacrificial film 141a is not removed by the etching. Either wet etching or dry etching can be performed for the etching of the protective film 143a. With the use of dry etching, a reduction in a processing pattern of the protective film 143a can be inhibited.

Next, the resist masks 145a are removed (FIG. 7D).

The resist masks 145a can be removed by wet etching or dry etching. It is particularly preferable to perform dry etching (also referred to as plasma ashing) using an oxygen gas as an etching gas to remove the resist masks 145a.

At this time, the resist masks 145a are removed in a state where the sacrificial film 141a is provided over the functional film 119Rf; thus, the influence on the functional film 119Rf, the light-emitting film 117Rf, the functional film 115Rf, and the functional film 113Rf is inhibited. In particular, when the light-emitting film 117Rf is exposed to oxygen, electrical characteristics are adversely affected in some cases; therefore, removal of the resist masks 145a in the state where the sacrificial film 141a is provided over the functional film 119Rf is suitable when etching using an oxygen gas, such as plasma ashing, is performed.

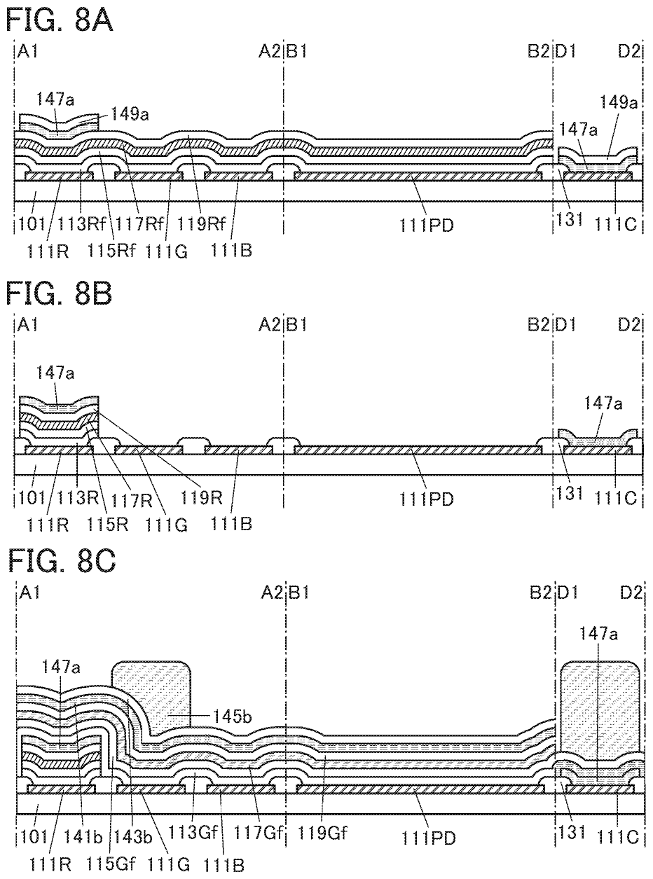

Next, part of the sacrificial film 141a that is not covered with the protective layer 149a is removed by etching with the use of the protective layer 149a as a mask, so that a sacrificial layer 147a is formed (FIG. 8A). At this time, the sacrificial layer 147a is concurrently formed also over the connection electrode 111C.

Either wet etching or dry etching can be performed for the etching of the sacrificial film 141a. The use of a dry etching method is preferable because pattern shrinkage can be inhibited.

Then, the protective layer 149a is removed by etching and parts of the functional film 119Rf, the light-emitting film 117Rf, the functional film 115Rf, and the functional film 113Rf that are not covered with the sacrificial layer 147a are removed by etching, so that the electron-transport layer 119R, the light-emitting layer 117R, the hole-transport layer 115R, and the hole-injection layer 113R are formed (FIG. 8B).

In particular, for etching of the functional film 119Rf, the light-emitting film 117Rf, the functional film 115Rf, and the functional film 113Rf, it is preferable to use dry etching using an etching gas that does not contain oxygen as its main component. Accordingly, a change in the quality of the functional film 119Rf, the light-emitting film 117Rf, the functional film 115Rf, and the functional film 113Rf can be inhibited, which leads to a highly reliable display device. Examples of the etching gas that does not contain oxygen as its main component include CF₄, C₄F₈, SF₆, CHF₃, Cl₂, H₂O, BCl₃, Hz, and a noble gas such as He. Alternatively, a mixed gas of the above gas and a dilution gas that does not contain oxygen can be used as the etching gas.

Then, a functional film 113Gf to be the hole-injection layer 113G in a later step, a functional film 115Gf to be the hole-transport layer 115G in a later step, a light-emitting film 117Gf to be the light-emitting layer 117G in a later step, and a functional film 119Gf to be the electron-transport layer 119G in a later step are sequentially formed over the sacrificial layer 147a, the insulating layer 131, the pixel electrode 111G, the pixel electrode 111B, and the pixel electrode 111PD. At this time, it is preferable not to provide the functional film 113Gf, the functional film 115Gf, the light-emitting film 117Gf, and the functional film 119Gf over the connection electrode 111C.

For a deposition method and the like of the functional film 113Gf, the functional film 115Gf, the light-emitting film 117Gf, and the functional film 119Gf, the description of the deposition method and the like of the functional film 113Rf, the functional film 115Rf, the light-emitting film 117Rf, and the functional film 119Rf can be referred to.

Then, a sacrificial film 141b is formed over the functional film 119Gf. The sacrificial film 141b can be formed in a manner similar to that for the sacrificial film 141a. In particular, for the sacrificial film 141b, it is preferable to use the same material as that for the sacrificial film 141a.

At this time, the sacrificial film 141b is concurrently deposited also over the connection electrode 111C to cover the sacrificial layer 147a.

Next, a protective film 143b is formed over the sacrificial film 141b. The protective film 143b can be formed in a manner similar to that for the protective film 143a. In particular, for the protective film 143b, it is preferable to use the same material as that for the protective film 143a.

Then, over the protective film 143b, a resist mask 145b is formed in each of a position overlapped with the pixel electrode 111G and a position overlapped with the connection electrode 111C (FIG. 8C).

The resist mask 145b can be formed in a manner similar to that for the resist mask 145a.

Next, part of the protective film 143b that is not covered with the resist mask 145b is removed by etching, so that a protective layer 149b is formed. At this time, the protective layer 149b is concurrently formed also over the connection electrode 111C.

For etching of the protective film 143b, the description of the protective film 143a can 35 be referred to.

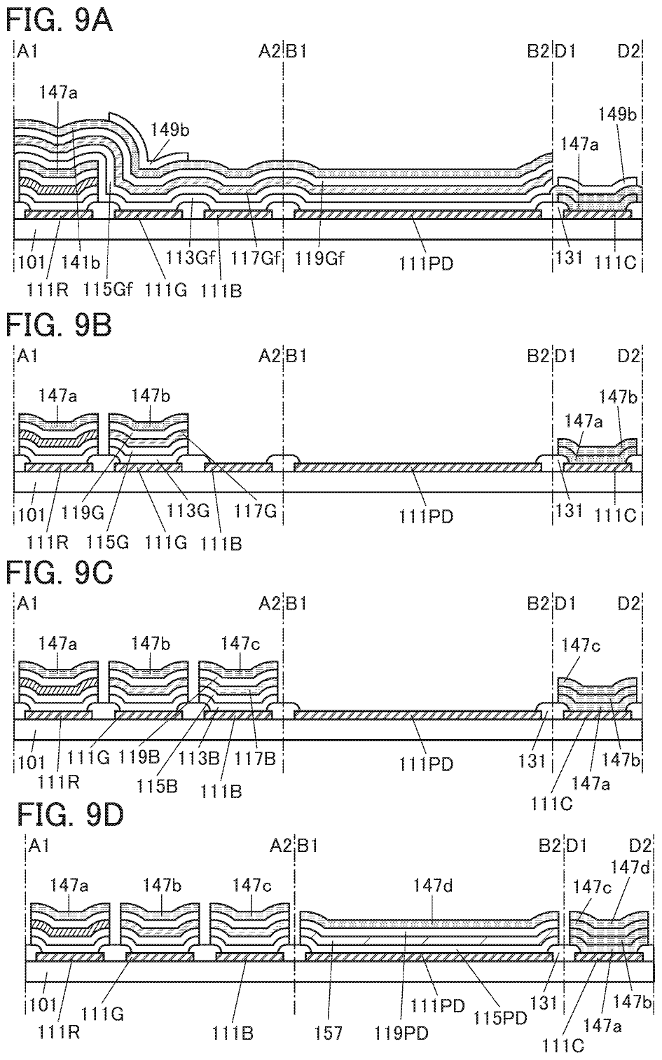

Next, the resist masks 145a are removed (FIG. 9A). For removal of the resist masks 145b, the description of the resist masks 145a can be referred to.

Next, part of the sacrificial film 141b that is not covered with the protective layer 149b is removed by etching with the use of the protective layer 149b as a mask, so that a sacrificial layer 147b is formed. At this time, the sacrificial layer 147b is concurrently formed also over the connection electrode 111C. The sacrificial layer 147a and the sacrificial layer 147b are stacked over the connection electrode 111C.

For etching of the sacrificial film 141b, the description of the sacrificial film 141a can be referred to.

Then, the protective layer 149b is removed by etching and parts of the functional film 119Gf, the light-emitting film 117Gf, the functional film 115Gf, and the functional film 113Gf that are not covered with the sacrificial layer 147b are removed by etching, so that the electron-transport layer 119G, the light-emitting layer 117G, the hole-transport layer 115G, and the hole-injection layer 113G are formed (FIG. 9B).

For etching of the functional film 119Gf, the light-emitting film 117Gf, the functional film 115Gf, the functional film 113Gf, and the protective layer 149b, the above description of the above functional film 119Rf, the light-emitting film 117Rf, the functional film 115Rf, the functional film 113Rf, and the protective layer 149a can be referred to.

At this time, the electron-transport layer 119R, the light-emitting layer 117R, the hole-transport layer 115R, and the hole-injection layer 113R are protected by the sacrificial layer 147a and thus can be prevented from being damaged in a step of etching the functional film 119Gf, the light-emitting film 117Gf, the functional film 115Gf, and the functional film 113Gf.

In this manner, the hole-injection layer 113R, the hole-transport layer 115R, the light-emitting layer 117R, and the electron-transport layer 119R can be formed separately from the hole-injection layer 113G, the hole-transport layer 115G, the light-emitting layer 117G, and the electron-transport layer 119G with high positional accuracy.

The hole-injection layer 113B, the hole-transport layer 115B, the light-emitting layer 117B, the electron-transport layer 119B, and a sacrificial layer 147c can be formed through a step similar to the above step (FIG. 9C). The sacrificial layer 147a, the sacrificial layer 147b, and the sacrificial layer 147c are stacked over the connection electrode 111C.

After the hole-injection layer 113B, the hole-transport layer 115B, the light-emitting layer 117B, the electron-transport layer 119B, and the sacrificial layer 147c are formed, the hole-transport layer 115PD, the light-receiving layer 157, the electron-transport layer 119PD, and a sacrificial layer 147d are formed through a step similar to the above step (FIG. 9D). The sacrificial layer 147a, the sacrificial layer 147b, the sacrificial layer 147c, and the sacrificial layer 147d are stacked over the connection electrode 111C. Note that the electron-transport layer 119PD is not necessarily formed.

In addition, in the case where a display device that includes the light-emitting element 110IR is manufactured, for example, after the hole-injection layer 113B, the hole-transport layer 115B, the light-emitting layer 117B, the electron-transport layer 119B, and the sacrificial layer 147c are formed and before the hole-transport layer 115PD, the light-receiving layer 157, the electron-transport layer 119PD, and the sacrificial layer 147d are formed, the hole-injection layer 11318, the hole-transport layer 11518, the light-emitting layer 11718, the electron-transport layer 1191R, and a sacrificial layer are formed through a step similar to the above step. In that case, five sacrificial layers are stacked over the connection electrode 111C.

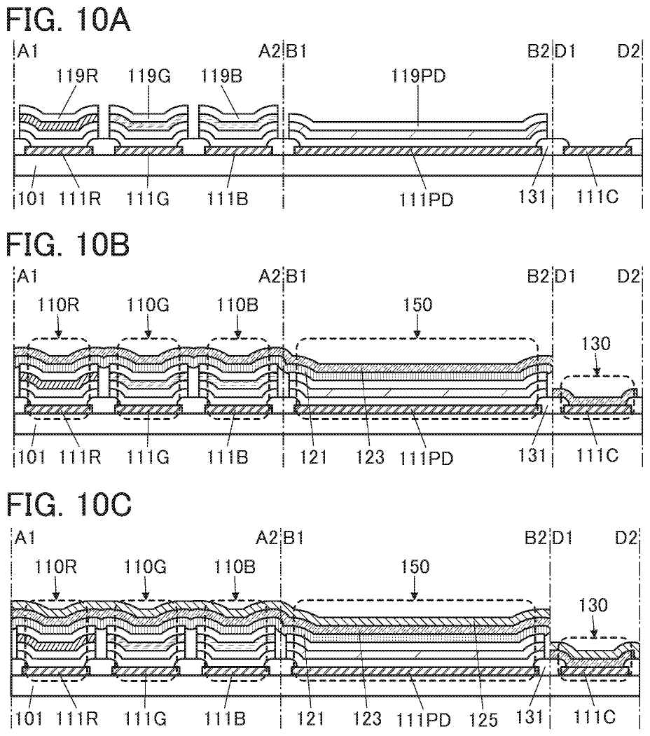

Then, the sacrificial layer 147a, the sacrificial layer 147b, the sacrificial layer 147c, and the sacrificial layer 147d are removed, so that a top surface of the electron-transport layer 119R, a top surface of the electron-transport layer 119G, a top surface of the electron-transport layer 119B, and a top surface of the electron-transport layer 119PD are exposed (FIG. 10A). At that time, the top surface of the connection electrode 111C is also exposed.

The sacrificial layer 147a, the sacrificial layer 147b, the sacrificial layer 147c, and the sacrificial layer 147d can be removed by wet etching or dry etching. At this time, it is preferable to use a method that causes damage to the hole-injection layer 113, the hole-transport layer 115, the light-emitting layer 117, the light-receiving layer 157, and the electron-transport layer 119 as little as possible. In particular, a wet etching method is preferably used. For example, it is preferable to use wet etching using a tetramethyl ammonium hydroxide (TMAH) aqueous solution, diluted hydrofluoric acid, oxalic acid, phosphoric acid, acetic acid, nitric acid, or a mixed solution thereof.

Alternatively, the sacrificial layer 147a, the sacrificial layer 147b, the sacrificial layer 147c, and the sacrificial layer 147d are preferably removed by being dissolved in a solvent such as water or alcohol. Here, as alcohol in which the sacrificial layer 147a, the sacrificial layer 147b, the sacrificial layer 147c, and the sacrificial layer 147d can be dissolved, a variety of alcohols such as ethyl alcohol, methyl alcohol, isopropyl alcohol (IPA), and glycerin can be used.

After the sacrificial layer 147a, the sacrificial layer 147b, the sacrificial layer 147c, and the sacrificial layer 147d are removed, drying treatment is preferably performed in order to remove water contained in the light-emitting layer 117R, the light-emitting layer 117G, the light-emitting layer 117B, the light-receiving layer 157, and the like and water adsorbed on surfaces of the light-emitting layer 117R, the light-emitting layer 117G, the light-emitting layer 117B, the light-receiving layer 157, and the like. For example, heat treatment is preferably performed in an inert gas atmosphere or a reduced-pressure atmosphere. The heat treatment can be performed at a substrate temperature of higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere because drying at a lower temperature is possible.

In this manner, the light-emitting layer 117R, the light-emitting layer 117G, the light-emitting layer 117B, the light-receiving layer 157, and the like can be separately formed.

Then, the common layer 121 is formed over the electron-transport layer 119R, the electron-transport layer 119G, the electron-transport layer 119B, and the electron-transport layer 119PD. As described above, a gap can be formed between the common layer 121 and the insulating layer 131.

The common layer 121 can be formed by, for example, an evaporation method, a sputtering method, an inkjet method, or the like. In the case where the common layer 121 is formed by an evaporation method, the common layer 121 is preferably formed using a shielding mask so as not to be formed over the connection electrode 111C.

Then, the common electrode 123 is formed to cover the common layer 121 and the connection electrode 111C (FIG. 10B).

The common electrode 123 can be formed by a deposition method such as an evaporation method or a sputtering method. Alternatively, a film formed by an evaporation method and a film formed by a sputtering method may be stacked. In that case, the common electrode 123 is preferably formed so as to cover a region where the common layer 121 is deposited. That is, a structure in which an end portion of the common layer 121 is overlapped with the common electrode 123 can be obtained. The common electrode 123 is preferably formed using a shielding mask.

The common electrode 123 is electrically connected to the connection electrode 111C outside a display portion.

Then, the protective layer 125 is formed over the common electrode 123 (FIG. 10C). An inorganic insulating film used for the protective layer 125 is preferably deposited by a sputtering method, a PECVD method, or an ALD method. In particular, an ALD method is preferable because it provides excellent step coverage and is less likely to cause a defect such as a pinhole. In addition, an organic insulating film is preferably formed by an inkjet method because a uniform film can be formed in a desired area.

In the above manner, the display device 10 can be manufactured.

Note that although the common electrode 123 and the common layer 121 are formed so as to have different top surface shapes, they may be formed in the same region.

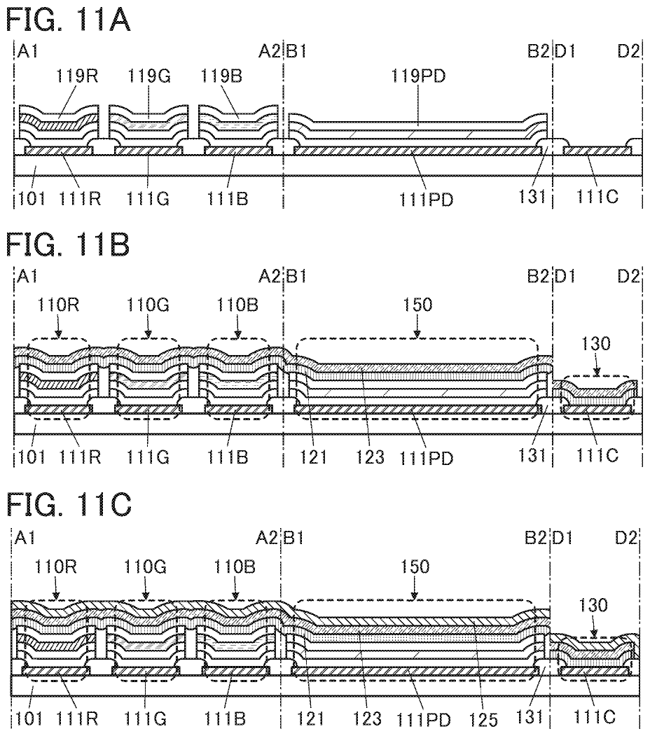

FIG. 11A is a schematic cross-sectional view after the removal of the sacrificial layers in the above description. Subsequently, as illustrated in FIG. 11B, the common layer 121 and the common electrode 123 are formed using the same shielding mask or without using any shielding mask. This can reduce manufacturing cost compared to the case where different shielding masks are used.

In this case, as illustrated in FIG. 11B, in the connection portion 130, the common layer 121 is interposed between the connection electrode 111C and the common electrode 123. In this case, for the common layer 121, a material with as low electric resistance as possible is preferably used. Alternatively, it is preferable to form the common layer 121 as thin as possible, in which case the electric resistance of the common layer 121 in the thickness direction can be reduced. For example, an electron-injection or hole-injection material with a thickness greater than or equal to 1 nm and less than or equal to 5 nm, preferably greater than or equal to 1 nm and less than or equal to 3 nm, is used for the common layer 121, whereby electric resistance between the connection electrode 111C and the common electrode 123 can be negligibly small in some cases.

Subsequently, the protective layer 125 is formed as illustrated in FIG. 11C. In this case, as illustrated in FIG. 11C, the protective layer 125 is preferably provided to cover an end portion of the common electrode 123 and the end portion of the common layer 121. This can effectively prevent diffusion of impurities such as water or hydrogen from the outside to the common layer 121 and to the interface between the common layer 121 and the common electrode 123.

The above is the description of the example of the manufacturing method of a display device.

As described above, in the method for manufacturing the display device according to one embodiment of the present invention, the light-emitting elements 110 can be formed separately without using a shadow mask such as a metal mask. This enables further miniaturization of subpixels compared to the case of separately forming the light-emitting elements 110 by using a shadow mask and an increase in pixel aperture ratio. Moreover, since the light-emitting layers 117 can be formed separately, it is possible to achieve a display device that performs extremely clear display with high contrast and high display quality.

Miniaturization of subpixels enables providing subpixels that do not contribute to display in a pixel. For example, a subpixel including the light-receiving element 150 can be provided in a pixel, and a subpixel including the light-emitting element 110IR that emits infrared light can be provided in the pixel. Even in the case where subpixels that do not contribute to display are provided in a pixel, the display device according to one embodiment of the present invention can inhibit a decrease in pixel density. For example, the pixel density can be higher than or equal to 400 ppi, can be higher than or equal to 1000 ppi, can be higher than or equal to 3000 ppi, or can be higher than or equal to 5000 ppi.

### Structure Example 2

A structure example of a display device whose structure is partly different from that of Structure example 1 described above is described below. Portions similar to those described above are not described below in some cases.

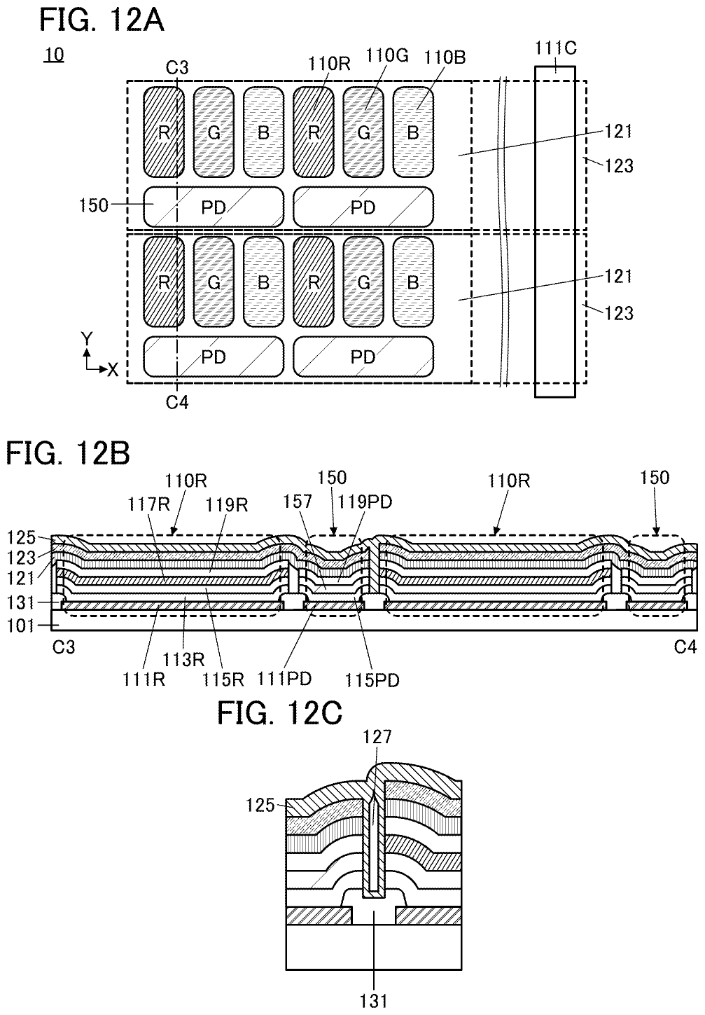

FIG. 12A is a schematic top view illustrating a structure example of the display device 10, which is a modification example of the display device 10 illustrated in FIG. 2A. The display device 10 illustrated in FIG. 12A is different from the display device 10 illustrated in FIG. 2A in the shape of the common layer 121 and the shape of the common electrode 123. In FIG. 12A, the outlines of the common electrode 123 and the common layer 121 are denoted by dashed lines.

FIG. 12B is a cross-sectional view taken along dashed-dotted line C3-C4 in FIG. 12A and illustrates a cross section in the Y direction. As illustrated in FIG. 12A and FIG. 12B, the common layer 121 and the common electrode 123 are divided between adjacent pixels. In other words, each of the common layer 121 and the common electrode 123 has end portions in regions overlapped with the insulating layer 131.

FIG. 12C is an enlarged cross-sectional view in which the light-receiving element 150 and the light-emitting element 110R provided in adjacent pixels are partly extracted from FIG. 12B. A depression is formed in part of a top surface of the insulating layer 131 as illustrated in FIG. 12C in some cases. In that case, the protective layer 125 is preferably provided along and in contact with the surface of the depression of the insulating layer 131. This is preferable because the contact area between the insulating layer 131 and the protective layer 125 is increased and the adhesion between them is improved.

As illustrated in FIG. 12C, a gap (also referred to as a void, a space, or the like) 127 is provided above the insulating layer 131 in some cases. Because of the high aspect ratio in the opening portion that separates the adjacent pixels, the gap 127 is formed when the protective layer 125 is formed. The gap 127 may be under reduced pressure or atmospheric pressure. The gap 127 may contain air, nitrogen, a gas such as a noble gas, a deposition gas used for the deposition of the protective layer 125, for example.

Although not illustrated here, the light-emitting element 110G and the light-emitting element 110B can have a similar structure.

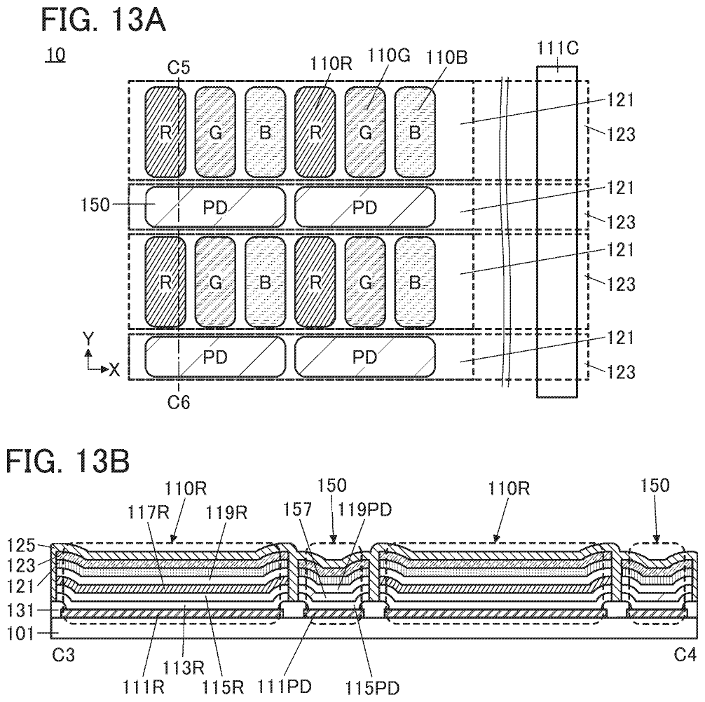

FIG. 13A is a schematic top view illustrating a structure example of the display device 10, which is a variation example of the display device 10 illustrated in FIG. 12A. FIG. 13B is a cross-sectional view taken along dashed-dotted line C5-C6 in FIG. 13A and illustrates a cross 35 section in the Y direction. The display device 10 illustrated in FIG. 13A and FIG. 13B is different from the display device 10 illustrated in FIG. 12A and FIG. 12B in the separation of the common layer 121 and the common electrode 123 not only in adjacent pixels but also in one pixel.

At least part of the structure examples, the drawings corresponding thereto, and the like shown in this embodiment as examples can be combined with the other structure examples, the other drawings, and the like as appropriate.

At least part of this embodiment can be implemented in combination with the other embodiments described in this specification as appropriate.

### Embodiment 2

In this embodiment, structure examples of a display device of one embodiment of the present invention are described.

### Structure Example 1

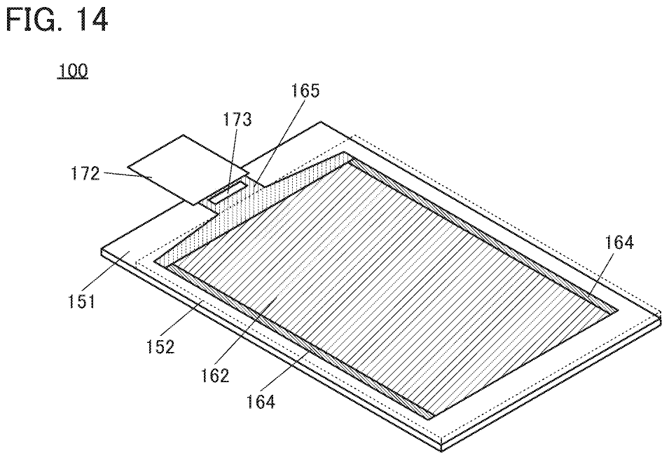

FIG. 14 is a perspective view illustrating a structure example of a display device 100. The display device 100 has a structure in which a substrate 151 and a substrate 152 are attached to each other. In FIG. 14, the substrate 152 is denoted by a dashed line.

The display device 100 includes a display portion 162, a circuit 164, a wiring 165, and the like. FIG. 14 also illustrates an example in which an IC (integrated circuit) 173 and an FPC 172 are mounted on the display device 100. Therefore, the structure illustrated in FIG. 14 can be regarded as a display module including the display device, the IC, and the FPC.

The circuit 164 can be a gate driver, for example. A signal and power can be supplied to the circuit 164 through the wiring 165, for example. The signal and the power can be input to the wiring 165 through the FPC 172 from the outside of the display device 10, for example. Alternatively, the IC 173 can generate the signal and the power and output the signal and the power to the wiring 165.

Although FIG. 14 illustrates an example in which the IC 173 is provided on the substrate 151 by a COG (Chip On Glass) method, a TCP (Tape Carrier Package) method, a COF (Chip On Film) method, or the like may be used.

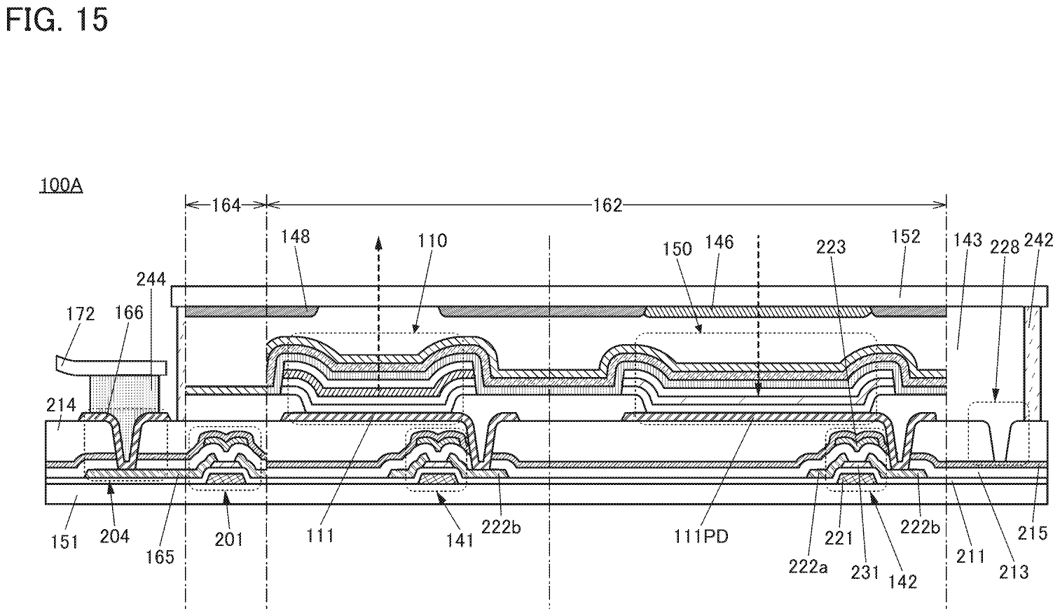

FIG. 15 is a diagram illustrating an example of cross sections of part of a region including the FPC 172, part of a region including the circuit 164, part of a region including the display portion 162, and part of a region including an end portion in the display device 100 illustrated in FIG. 14. Note that the display device 100 illustrated in FIG. 15 is a display device 100A.

The display device 100A includes a transistor 201, a transistor 141, a transistor 142, the light-emitting element 110, the light-receiving element 150, and the like between the substrate 151 and the substrate 152.

The substrate 152 and an insulating layer 214 are bonded to each other with an adhesive layer 242. A solid sealing structure, a hollow sealing structure, or the like can be employed to seal the light-emitting element 110 and the light-receiving element 150. A hollow sealing structure is employed in which a space 143 surrounded by the substrate 152, the adhesive layer 242, and the insulating layer 214 is filled with an inert gas (nitrogen, argon, or the like). The adhesive layer 242 may be provided to be overlapped with the light-emitting element 110. In addition, a region surrounded by the substrate 152, the adhesive layer 242, and the insulating layer 214 may be filled with a resin different from that of the adhesive layer 242.

The pixel electrode 111 included in the light-emitting element 110 is electrically connected to the conductive layer 222b included in the transistor 142 through an opening provided in the insulating layer 214. The transistor 142 has a function of controlling the driving of the light-emitting element 110. The pixel electrode 111PD included in the light-emitting element 150 is electrically connected to the conductive layer 222b included in the transistor 141 through an opening provided in the insulating layer 214.

Light from the light-emitting element 110 is emitted toward the substrate 152 side. In addition, light enters the light-receiving element 150 through the substrate 152 and the space 143. For the substrate 152, a material having a high transmitting property with respect to visible light and infrared light is preferably used.

A light-blocking layer 148 is provided on a surface of the substrate 152 on the substrate 151 side. The light-blocking layer 148 has openings in a position overlapped with the light-receiving element 150 and in a position overlapped with the light-emitting element 110. In addition, a filter 146 that filters out ultraviolet light is provided in a position overlapped with the light-receiving element 150. Note that a structure without the filter 146 can be employed.

The transistor 201, the transistor 141, and the transistor 142 are all formed over the substrate 151. These transistors can be formed using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that there is no limitation on the number of gate insulating layers and the number of insulating layers covering the transistors, and each insulating layer may be either a single layer or two or more layers.

A material into which impurities such as water and hydrogen are less likely to diffuse is preferably used for at least one of the insulating layers that cover the transistors. This allows the insulating layer to serve as a barrier layer. Such a structure can effectively inhibit diffusion of impurities into the transistors from the outside and increase the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used. Alternatively, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film may be used. A stack including two or more of the above insulating films may also be used.

An organic insulating film is preferably used for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

Here, an organic insulating film often has a lower barrier property against impurities than an inorganic insulating film. Therefore, the organic insulating film preferably has an opening in the vicinity of an end portion of the display device 100A. This can inhibit diffusion of impurities from the end portion of the display device 100A through the organic insulating film. Alternatively, in order to prevent the organic insulating film from being exposed at the end portion of the display device 100A, the organic insulating film may be formed so that its end portion is positioned on the inner side compared to the end portion of the display device 100A.

In a region 228 illustrated in FIG. 15, an opening is formed in the insulating layer 214. This can inhibit diffusion of impurities into the display portion 162 from the outside through the insulating layer 214 even when an organic insulating film is used as the insulating layer 214. Thus, the reliability of the display device 100A can be increased.

The transistor 201, the transistor 141, and the transistor 142 each include a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate. Here, a plurality of layers obtained by processing the same conductive film are illustrated with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structures of the transistors included in the display device of this embodiment. For example, a planar transistor, a staggered transistor, an inverted staggered transistor, or the like can be used. In addition, the transistor structure may be either a top-gate structure or a bottom-gate structure. Alternatively, gates may be provided above and below a semiconductor layer where a channel is formed.

A structure in which the semiconductor layer where a channel is formed is sandwiched between the two gates is used for the transistor 201, the transistor 141, and the transistor 142. The two gates may be connected to each other and supplied with the same signal to drive the transistor. Alternatively, one of the two gates may be supplied with a potential for controlling the threshold voltage of the transistor and the other may be supplied with a potential for driving.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

A semiconductor layer of a transistor preferably contains a metal oxide (also referred to as an oxide semiconductor). Alternatively, the semiconductor layer of the transistor may contain silicon. Examples of silicon include amorphous silicon and crystalline silicon (low-temperature polysilicon, single crystal silicon, and the like).

When the semiconductor layer contains a metal oxide, the metal oxide preferably contains at least indium or zinc as described above. In particular, indium and zinc are preferably contained. In addition to them, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The transistors included in the circuit 164 and the transistors included in the display portion 162 may have either the same structure or different structures. A plurality of transistors included in the circuit 164 may have either the same structure or two or more kinds of structures. Similarly, a plurality of transistors included in the display portion 162 may have either the same structure or two or more kinds of structures.

A connection portion 204 is provided in a region that is over the substrate 151 and not overlapped the substrate 152. In the connection portion 204, the wiring 165 is electrically connected to the FPC 172 through a conductive layer 166 and a connection layer 244. On a top surface of the connection portion 204, the conductive layer 166 obtained by processing the same conductive film as the pixel electrode 111 is exposed. Thus, the connection portion 204 and the FPC 172 can be electrically connected to each other through the connection layer 244.

A variety of optical members can be arranged on an outer side of the substrate 152. Examples of the optical members include a polarizing plate, a retardation plate, a light diffusion layer (a diffusion film or the like), an anti-reflective layer, and a light-condensing film. Furthermore, an antistatic film inhibiting attachment of dust, a water repellent film suppressing attachment of stain, a hard coat film inhibiting generation of a scratch caused by the use, a shock absorbing layer, or the like may be provided on the outer side of the substrate 152.

Glass, quartz, ceramic, sapphire, a resin, or the like can be used for the substrate 151 and the substrate 152.

For the adhesive layer, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. Alternatively, an adhesive sheet may be used, for example.

As the connection layer 244, an anisotropic conductive film (ACF) or an anisotropic conductive paste (ACP) can be used.

As materials that can be used for conductive layers such as a variety of wirings and electrodes that constitute a display device, in addition to a gate, a source, and a drain of a transistor, metals such as aluminum, titanium, chromium, nickel, copper, yttrium, zirconium, molybdenum, silver, tantalum, or tungsten, an alloy containing the metal as its main component, and the like can be given. A film containing these materials can be used as a single-layer structure or a stacked-layer structure.

In addition, as a light-transmitting conductive material, a conductive oxide such as indium oxide, indium tin oxide, indium zinc oxide, zinc oxide, or zinc oxide containing gallium can be used or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) or the like may be used. Note that in the case of using the metal material or the alloy material (or the nitride thereof), the material is made thin enough to have a light-transmitting property. Furthermore, a stacked-layer film of the above materials can be used for a conductive layer. For example, a stacked-layer film of indium tin oxide and an alloy of silver and magnesium, or the like is preferably used for increased conductivity. They can also be used for conductive layers such as a variety of wirings and electrodes that constitute a display device, and conductive layers (conductive layers functioning as a pixel electrode or a common electrode) included in a display element.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

### Structure Example 2

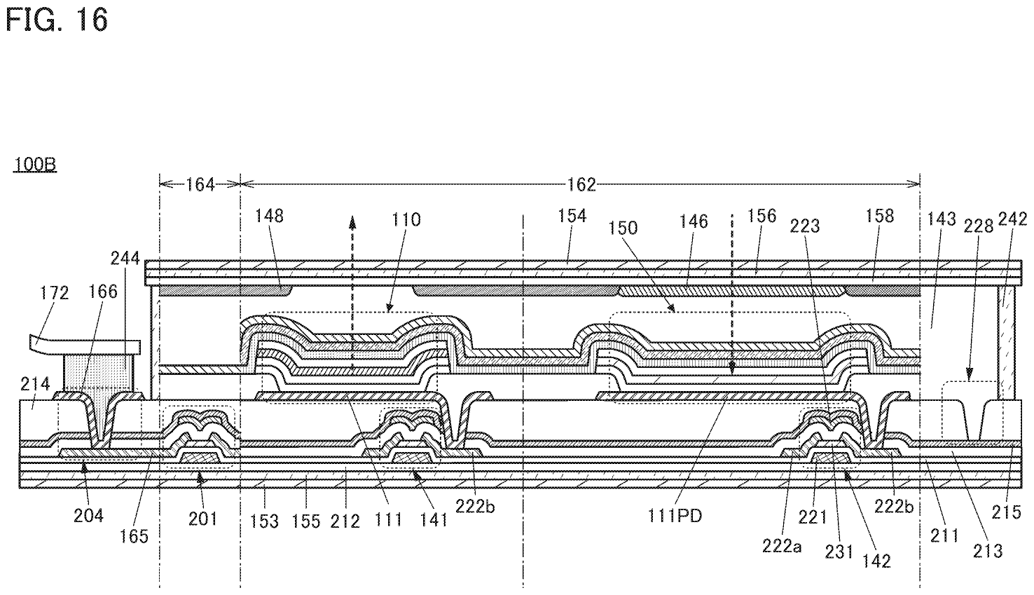

FIG. 16 is a cross-sectional view illustrating a structure example of a display device 100B and is a modification example of the display device 100A. The display device 100B differs from the display device 100A in that a substrate 153 instead of the substrate 151, an adhesive layer 155, and an insulating layer 212 are included and that a substrate 154 instead of the substrate 152, an adhesive layer 156, and an insulating layer 158 are included.

In the display device 100B, the substrate 153 and the insulating layer 212 are attached to each other with the adhesive layer 155. In addition, the substrate 154 and the insulating layer 158 are attached to each other with the adhesive layer 156.

When the display device 100B illustrated in FIG. 16 is manufactured, first, a first manufacture substrate provided with the insulating layer 212, each transistor, the light-emitting element 110, the light-receiving element 150, and the like and a second manufacture substrate provided with the insulating layer 158, the light-blocking layer 148, the filter 146, and the like are attached to each other with the adhesive layer 242. Then, the substrate 153 is attached to a surface where the first manufacture substrate is separated and exposed with the adhesive layer 155. Accordingly, each component formed over the first manufacture substrate is transferred onto the substrate 153. In addition, the substrate 154 is attached to a surface where the second manufacture substrate is separated and exposed with the adhesive layer 156. Accordingly, each component formed over the second manufacture substrate is transferred onto the substrate 154. Furthermore, the substrate 153 and the substrate 154 are preferably flexible. Accordingly, the display device 100B can be flexible. That is, the display device 100B can be a flexible display.

The inorganic insulating film that can be used for the insulating layer 211, the insulating layer 213, and the insulating layer 215 can be used for the insulating layer 212 and the insulating layer 158.

### Structure Example 3

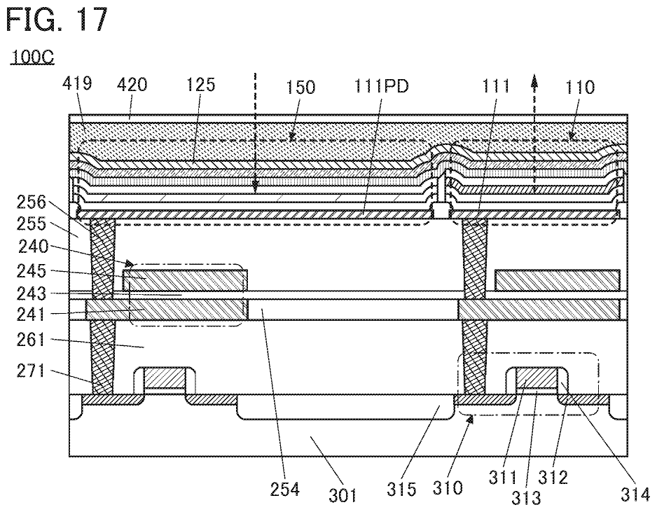

FIG. 17 is a cross-sectional view illustrating a structure example of a display device 100C. The display device 100C includes a substrate 301, the light-emitting element 110, the light-receiving element 150, a capacitor 240, and a transistor 310. The substrate 301 corresponds to the substrate 151 in FIG. 14, for example.

The transistor 310 is a transistor that includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance regions 312 are regions where the substrate 301 is doped with an impurity, and function as a source and a drain. The insulating layer 314 is provided to cover a side surface of the conductive layer 311.

In addition, an element isolation layer 315 is provided between two adjacent transistors 310 to be embedded in the substrate 301.

Furthermore, an insulating layer 261 is provided to cover the transistor 310, and the capacitor 240 is provided over the insulating layer 261.

The capacitor 240 includes a conductive layer 241, a conductive layer 245, and an insulating layer 243 between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapped with the conductive layer 241 with the insulating layer 243 therebetween.

An insulating layer 255 is provided to cover the capacitor 240, and the light-emitting element 110, the light-receiving element 150, and the like are provided over the insulating layer 255. The protective layer 125 is provided over the light-emitting element 110 and the light-receiving element 150, and a substrate 420 is attached to the top surface of the protective layer 125 with a resin layer 419. The substrate 420 corresponds to the substrate 152 in FIG. 14, for example.

The pixel electrode 111 of the light-emitting element 110 and the pixel electrode 111PD of the light-receiving element 150 are electrically connected to the one of the source and the drain of the transistor 310 through a plug 256 embedded in the insulating layer 255 and the insulating layer 243, the conductive layer 241 embedded in the insulating layer 254, and the plug 271 embedded in the insulating layer 261.

### STRUCTURE EXAMPLE 4

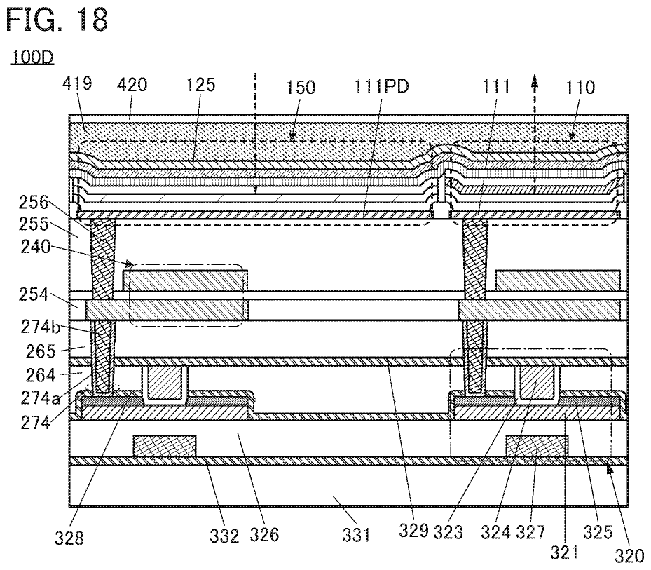

FIG. 18 is a cross-sectional view illustrating a structure example of a display device 100D. The display device 100D differs from the display device 100C mainly in a transistor structure. Note that the description of portions similar to those in the display device 100C is omitted in some cases.

A transistor 320 is a transistor that contains a metal oxide in a semiconductor layer where a channel is formed (hereinafter also referred to as an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 151 in FIG. 14, for example. As the substrate 331, an insulating substrate or a semiconductor substrate can be used.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. For the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used for at least part of the insulating layer 326 that is in contact with the semiconductor layer 321. A top surface of the insulating layer 326 is preferably planarized.

The semiconductor layer 321 is provided over the insulating layer 326. The semiconductor layer 321 preferably includes a film of a metal oxide that has semiconductor characteristics.

The pair of conductive layers 325 are provided on and in contact with the semiconductor layer 321 and function as a source electrode and a drain electrode.

In addition, an insulating layer 328 is provided to cover top surfaces and side surfaces of the pair of conductive layers 325, side surfaces of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. For the insulating layer 328, an insulating film similar to the insulating layer 332 can be used.

An opening that reaches the semiconductor layer 321 is provided in the insulating layer 328 and the insulating layer 264. The insulating layer 323 that is in contact with side surfaces of the insulating layer 264, the insulating layer 328, and the conductive layer 325 and a top surface of the semiconductor layer 321 and the conductive layer 324 are embedded in the opening. The conductive layer 324 functions as a second gate electrode, and the insulating layer 323 functions as a second gate insulating layer.

A top surface of the conductive layer 324, a top surface of the insulating layer 323, and a top surface of the insulating layer 264 are planarized so that they are substantially level with each other, and an insulating layer 329 and an insulating layer 265 are provided to cover these layers.

The insulating layer 264 and the insulating layer 265 each function as an interlayer 35 insulating layer. The insulating layer 329 functions as a barrier layer that prevents diffusion of impurities such as water or hydrogen from the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, the insulating layer 264, and the insulating layer 328. Here, the plug 274 preferably includes a conductive layer 274a that covers a side surface of an opening formed in the insulating layer 265, the insulating layer 329, the insulating layer 264, and the insulating layer 328 and part of a top surface of the conductive layer 325, and a conductive layer 274b in contact with a top surface of the conductive layer 274a. At this time, a conductive material in which hydrogen and oxygen are less likely to diffuse is preferably used for the conductive layer 274a.

The structures of the insulating layer 254 and components thereover up to the substrate 420 in the display device 100D are similar to those in the display device 100C.

### STRUCTURE EXAMPLE 5

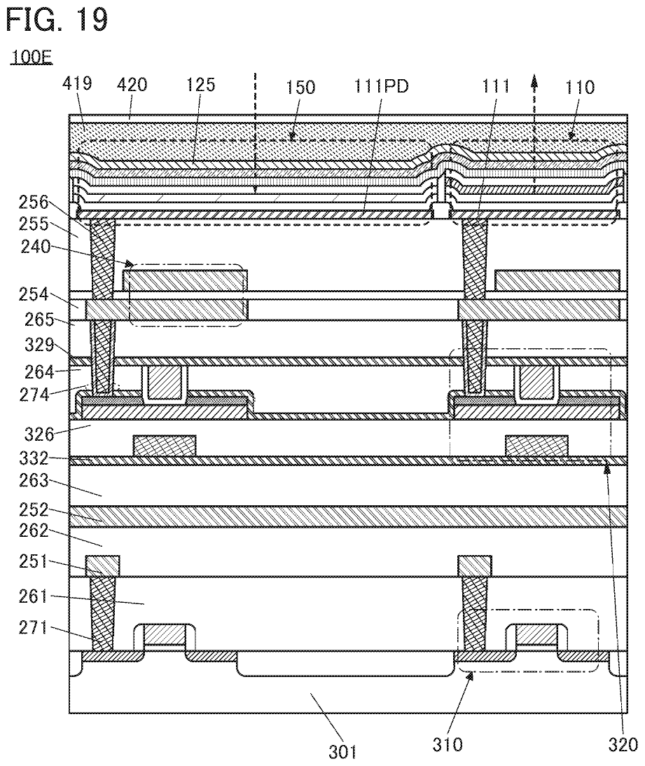

FIG. 19 is a cross-sectional view illustrating a structure example of a display device 100E. The display device 100E has a structure in which the transistor 310 whose channel is formed in the substrate 301 and the transistor 320 including a metal oxide in the semiconductor layer where the channel is formed are stacked. Note that the description of portions similar to those in the display device 100C or the display device 100D is omitted in some cases.

The insulating layer 261 is provided to cover the transistor 310, and a conductive layer 251 is provided over the insulating layer 261. In addition, an insulating layer 262 is provided to cover the conductive layer 251, and a conductive layer 252 is provided over the insulating layer 262. The conductive layer 251 and the conductive layer 252 each function as a wiring. Furthermore, an insulating layer 263 and the insulating layer 332 are provided to cover the conductive layer 252, and the transistor 320 is provided over the insulating layer 332. Moreover, the insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in a pixel circuit. In addition, the transistor 310 can be used as a transistor included in a pixel circuit or a transistor included in a driver circuit for driving the pixel circuit (a gate line driver circuit or a source line driver circuit). Furthermore, the transistor 310 and the transistor 320 can be used as transistors included in a variety of circuits such as an arithmetic circuit and a memory circuit.

With such a structure, not only the pixel circuit but also the driver circuit or the like can be formed directly under the light-emitting element; thus, the display device can be downsized as compared with the case where the driver circuit is provided around a display portion.

At least part of the structure examples, the drawings corresponding thereto, and the like shown in this embodiment as examples can be combined with the other structure examples, the other drawings, and the like as appropriate.

At least part of this embodiment can be implemented in combination with the other embodiments described in this specification as appropriate.

### Embodiment 3

In this embodiment, light-emitting elements that can be used in a display device of one embodiment of the present invention will be described.

### <Structure Example of Light-Emitting Element>

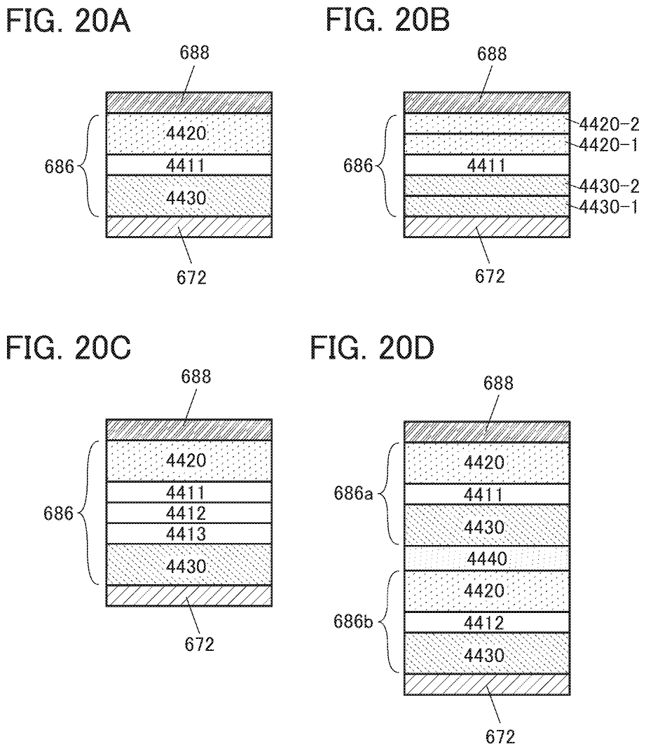

As shown in FIG. 20A, the light-emitting element includes an EL layer 686 between a pair of electrodes (an electrode 672 and an electrode 688). The EL layer 686 can be formed of a plurality of layers, i.e., a layer 4420, a light-emitting layer 4411, a layer 4430, and the like. The layer 4420 can include, for example, a layer containing a substance having a high electron-injection property (an electron-injection layer) and a layer containing a substance having a high electron-transport property (an electron-transport layer). The light-emitting layer 4411 contains a light-emitting compound, for example. The layer 4430 can include, for example, a layer containing a substance having a high hole-injection property (a hole-injection layer) and a layer containing a substance having a high hole-transport property (a hole-transport layer).

The structure including the layer 4420, the light-emitting layer 4411, and the layer 4430, which is provided between a pair of electrodes, can serve as a single light-emitting unit, and the structure in FIG. 20A is referred to as a single structure in this specification.

FIG. 20B is a variation example of the EL layer 686 included in the light-emitting element illustrated in FIG. 20A. Specifically, the light-emitting element illustrated in FIG. 20B includes a layer 4430-1 over the electrode 672, a layer 4430-2 over the layer 4430-1, the light-emitting layer 4411 over the layer 4430-2, a layer 4420-1 over the light-emitting layer 4411, a layer 4420-2 over the layer 4420-1, and the electrode 688 over the layer 4420-2. For example, when the electrode 672 is an anode and the electrode 688 is a cathode, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, when the electrode 672 is a cathode and the electrode 688 is an anode, the layer 4430-1 functions as an electron-injection layer, the layer 4430-2 functions as an electron-transport layer, the layer 4420-1 functions as a hole-transport layer, and the layer 4420-2 functions as a hole-injection layer. With such a layer structure, carriers can be efficiently injected to the light-emitting layer 4411, and the efficiency of the recombination of carriers in the light-emitting layer 4411 can be enhanced.

Note that the structure in which a plurality of light-emitting layers (the light-emitting layer 4411, a light-emitting layer 4412, and a light-emitting layer 4413) are provided between the layer 4420 and the layer 4430 as illustrated in FIG. 20C is a variation of the single structure.

The structure in which a plurality of light-emitting units (an EL layer 686a and an EL layer 686b) are connected in series with an intermediate layer (charge-generation layer) 4440 therebetween as illustrated in FIG. 20D is referred to as a tandem structure in this specification. In this specification and the like, the structure illustrated in FIG. 20D is referred to as a tandem structure; however, without being limited to this, a tandem structure may be referred to as a stack structure, for example. The tandem structure enables a light-emitting element capable of high luminance light emission.

Also in FIG. 20C and FIG. 20D, the layer 4420 and the layer 4430 may each have a stacked-layer structure of two or more layers as illustrated in FIG. 20B.

In the case where the above-described single structure and tandem structure and the SBS structure are compared with each other, the SBS structure, the tandem structure, and the single structure have lower power consumption in this order. To reduce power consumption, the SBS structure is preferably employed. Meanwhile, the single structure and the tandem structure are suitable in terms of lower manufacturing cost or higher manufacturing yield because the manufacturing processes of the single structure and the tandem structure are simpler than that of the SBS structure.

The emission color of the light-emitting elements can be red, green, blue, cyan, magenta, yellow, white, or the like depending on materials that constitute the EL layer 686. Furthermore, color purity can be further increased when the light-emitting element has a microcavity structure.

The light-emitting element that emits white light preferably contains two or more kinds of light-emitting substances in the light-emitting layer. To obtain white light emission, two or more kinds of light-emitting substances are selected so that their emission colors have a relationship of complementary colors. For example, when the emission color of a first light-emitting layer and the emission color of a second light-emitting layer have a relationship of complementary colors, it is possible to obtain the light-emitting element that emits white light as a whole. The same applies to a light-emitting element including three or more light-emitting layers.

The light-emitting layer preferably contains two or more kinds of light-emitting substances that emit light of red (R), green (G), blue (B), yellow (Y), orange (O), and the like. At least part of the structure examples, the drawings corresponding thereto, and the like shown in this embodiment as examples can be combined with the other structure examples, the other drawings, and the like as appropriate.

At least part of this embodiment can be implemented in combination with the other embodiments described in this specification as appropriate.

### Embodiment 4

In this embodiment, detailed structures of the light-emitting element, the light-receiving element, and the light-emitting and light-receiving element which can be used in the display device of one embodiment of the present invention are described.

The display device of one embodiment of the present invention can have any of the following structures: a top-emission structure in which light is emitted in a direction opposite to the substrate where the light-emitting elements are formed, a bottom-emission structure in which light is emitted toward the substrate where the light-emitting elements are formed, and a dual-emission structure in which light is emitted toward both surfaces.

In this embodiment, a top-emission display device is described as an example.

In this specification and the like, unless otherwise specified, in describing a structure including a plurality of components (e.g., light-emitting elements or light-emitting layers), alphabets are not added when a common part for the components is described. For example, when a common part of a light-emitting layer 383R, a light-emitting layer 383G, and the like is described, the light-emitting layers are simply referred to as a light-emitting layer 383, in some cases.

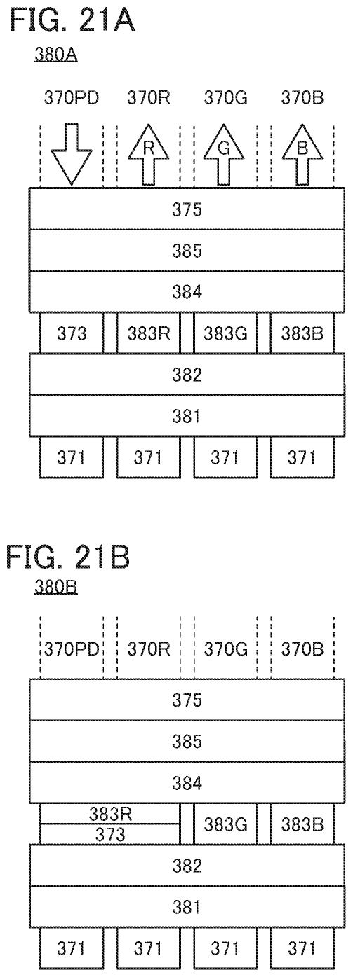

A display device 380A illustrated in FIG. 21A includes a light-receiving element 370PD, a light-emitting element 370R that emits red (R) light, a light-emitting element 370G that emits green (G) light, and a light-emitting element 370B that emits blue (B) light.

Each of the light-emitting elements includes a pixel electrode 371, a hole-injection layer 381, a hole-transport layer 382, a light-emitting layer, an electron-transport layer 384, an electron-injection layer 385, and a common electrode 375, which are stacked in this order. The light-emitting element 370R includes the light-emitting layer 383R, the light-emitting element 370G includes the light-emitting layer 383G, and the light-emitting element 370B includes a light-emitting layer 383B. The light-emitting layer 383R contains a light-emitting substance that emits red light, the light-emitting layer 383G contains a light-emitting substance that emits green light, and the light-emitting layer 383B contains a light-emitting substance that emits blue light.

The light-emitting elements are electroluminescent elements that emit light to the common electrode 375 side by voltage application between the pixel electrodes 371 and the common electrode 375.

The light-receiving element 370PD includes the pixel electrode 371, the hole-injection layer 381, the hole-transport layer 382, an active layer 373, the electron-transport layer 384, the electron-injection layer 385, and the common electrode 375, which are stacked in this order.

The light-receiving element 370PD is a photoelectric conversion element that receives 35 light entering from the outside of the display device 380A and converts it into an electric signal.

In the description made in this embodiment, the pixel electrode 371 functions as an anode and the common electrode 375 functions as a cathode in both of the light-emitting element and the light-receiving element. In other words, when the light-receiving element is driven by application of reverse bias between the pixel electrode 371 and the common electrode 375, light incident on the light-receiving element can be detected and charge can be generated and extracted as current.

In the display device of this embodiment, an organic compound is used for the active layer 373 of the light-receiving element 370PD. In the light-receiving element 370PD, the layers other than the active layer 373 can have structures in common with the layers in the light-emitting elements. Therefore, the light-receiving element 370PD can be formed concurrently with the formation of the light-emitting elements only by adding a step of forming the active layer 373 in the manufacturing process of the light-emitting elements. The light-emitting elements and the light-receiving element 370PD can be formed over one substrate. Accordingly, the light-receiving element 370PD can be incorporated into the display device without a significant increase in the number of manufacturing steps.

The display device 380A is an example in which the light-receiving element 370PD and the light-emitting elements have a common structure except that the active layer 373 of the light-receiving element 370PD and the light-emitting layers 383 of the light-emitting elements are separately formed. Note that the structures of the light-receiving element 370PD and the light-emitting elements are not limited thereto. The light-receiving element 370PD and the light-emitting elements may include separately formed layers other than the active layer 373 and the light-emitting layers 383. The light-receiving element 370PD and the light-emitting elements preferably include at least one layer used in common (common layer). Thus, the light-receiving element 370PD can be incorporated into the display device without a significant increase in the number of manufacturing steps.

A conductive film that transmits visible light is used as the electrode through which light is extracted, which is either the pixel electrode 371 or the common electrode 375. A conductive film that reflects visible light is preferably used as the electrode through which light is not extracted.

The light-emitting element includes at least the light-emitting layer 383. The light-emitting element may further include, as a layer other than the light-emitting layer 383, a layer containing a substance with a high hole-injection property, a substance with a high hole-transport property, a hole-blocking material, a substance with a high electron-transport property, a substance with a high electron-injection property, an electron-blocking material, a substance with a bipolar property (a substance with a high electron- and hole-transport property), or the like.

For example, the light-emitting elements and the light-receiving element can share at least one of the hole-injection layer, the hole-transport layer, the electron-transport layer, and the electron-injection layer. Furthermore, at least one of the hole-injection layer, the hole-transport layer, the electron-transport layer, and the electron-injection layer can be separately formed for the light-emitting elements and the light-receiving element.

The active layer 373 includes a semiconductor. Examples of the semiconductor include an inorganic semiconductor such as silicon and an organic semiconductor containing an organic compound. This embodiment shows an example in which an organic semiconductor is used as the semiconductor included in the active layer 373. The use of an organic semiconductor is preferable because the light-emitting layer 383 and the active layer 373 can be formed by the same method (e.g., a vacuum evaporation method) and thus the same manufacturing apparatus can be used.

Examples of an n-type semiconductor material contained in the active layer 373 are electron-accepting organic semiconductor materials such as fullerene (e.g., C₆₀ and C₇₀) and a fullerene derivative. Fullerene has a soccer ball-like shape, which is energetically stable. Both the HOMO level and the LUMO level of fullerene are deep (low). Having a deep LUMO level, fullerene has an extremely high electron-accepting property (acceptor property). When π-electron conjugation (resonance) spreads in a plane as in benzene, the electron-donating property (donor property) usually increases. Although π-electrons widely spread in fullerene having a spherical shape, its electron-accepting property is high. The high electron-accepting property efficiently causes rapid charge separation and is useful for a light-receiving element. Both C₆₀ and C₇₀ have a wide absorption band in the visible light region, and C₇₀ is especially preferable because of having a larger π-electron conjugation system and a wider absorption band in the long wavelength region than C₆₀. Other examples of fullerene derivatives include [6,6]-phenyl-C₇₁-butyric acid methyl ester (abbreviation: PC70BM), [6,6]-phenyl-C₆₁-butyric acid methyl ester (abbreviation: PC60BM), and 1′,1″,4′,4″-tetrahydro-di[1,4]methanonaphthaleno[1,2:2′,3′,56,60:2″,3″][5,6]fullerene-C₆₀ (abbreviation: ICBA).

Examples of the n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer 373 include electron-donating organic semiconductor materials such as copper(II) phthalocyanine (CuPc), tetraphenyldibenzoperiflanthene (DBP), zinc phthalocyanine (ZnPc), tin phthalocyanine (SnPc), and quinacridone.

Examples of a p-type semiconductor material include a carbazole derivative, a thiophene derivative, a furan derivative, and a compound having an aromatic amine skeleton. Other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can improve the carrier-transport property.

For example, the active layer 373 is preferably formed by co-evaporation of an n-type semiconductor and a p-type semiconductor. Alternatively, the active layer 373 may be formed by stacking an n-type semiconductor and a p-type semiconductor.

Either a low molecular compound or a high molecular compound can be used for the light-emitting element and the light-receiving element, and an inorganic compound may be contained. Each of the layers included in the light-emitting element and the light-receiving element can be formed by an evaporation method (including a vacuum evaporation method), a transfer method, a printing method, an inkjet method, a coating method, or the like.

As the hole-transport material, a high molecular compound such as poly(3,4-ethylenedioxythiophene)/poly(styrenesulfonic acid) (PEDOT/PSS), or an inorganic compound such as molybdenum oxide or copper iodide (CuI) can be used, for example. As the electron-transport material, an inorganic compound such as zinc oxide (ZnO) can be used.

For the active layer 373, it is possible to use a high molecular compound that functions as a donor, such as poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H, 8H-benzo[1,2-c:4,5-c′]dithiophene-1,3-diyl]] polymer (abbreviation: PBDB-T) or a PBDB-T derivative. For example, a method of dispersing an acceptor material in PBTB-T or a PBDB-T derivative can be employed.

The active layer 373 may contain a mixture of three or more kinds of materials. For example, a third material may be mixed with an n-type semiconductor material and a p-type semiconductor material in order to extend the wavelength range. In this case, the third material may be a low molecular compound or a high molecular compound.

A display device 380B illustrated in FIG. 21B is different from the display device 380A in that the light-receiving element 370PD and the light-emitting element 370R have the same structure.

The light-receiving element 370PD and the light-emitting element 370R share the active layer 373 and the light-emitting layer 383R.

Here, it is preferable that the light-receiving element 370PD have a structure in common 35 with the light-emitting element that emits light with a wavelength longer than that of the light desired to be detected. For example, the light-receiving element 370PD having a structure in which blue light is detected can have a structure which is similar to that of one or both of the light-emitting element 370R and the light-emitting element 370G. For example, the light-receiving element 370PD having a structure in which green light is detected can have a structure similar to that of the light-emitting element 370R.

When the light-receiving element 370PD and the light-emitting element 370R have a common structure, the number of deposition steps and the number of masks can be smaller than those for the structure in which the light-receiving element 370PD and the light-emitting element 370R include separately formed layers. As a result, the number of manufacturing steps and the manufacturing cost of the display device can be reduced.

When the light-receiving element 370PD and the light-emitting element 370R have a common structure, a margin for misalignment can be narrower than that for the structure in which the light-receiving element 370PD and the light-emitting element 370R include separately formed layers. Accordingly, the aperture ratio of a pixel can be increased, so that the light extraction efficiency of the display device can be increased. This can extend the life of the light-emitting element. Furthermore, the display device can exhibit a high luminance. Moreover, the resolution of the display device can also be increased.

The light-emitting layer 383R contains a light-emitting material that emits red light. The active layer 373 contains an organic compound that absorbs light with a wavelength shorter than that of red light (e.g., one or both of green light and blue light). The active layer 373 preferably contains an organic compound that does not easily absorb red light and that absorbs light with a wavelength shorter than that of red light. In this way, red light can be efficiently extracted from the light-emitting element 370R, and the light-receiving element 370PD can detect light with a wavelength shorter than that of red light at high accuracy.

Although the light-emitting element 370R and the light-receiving element 370PD have the same structure in an example of the display device 380B, the light-emitting element 370R and the light-receiving element 370PD may include optical adjustment layers with different thicknesses.

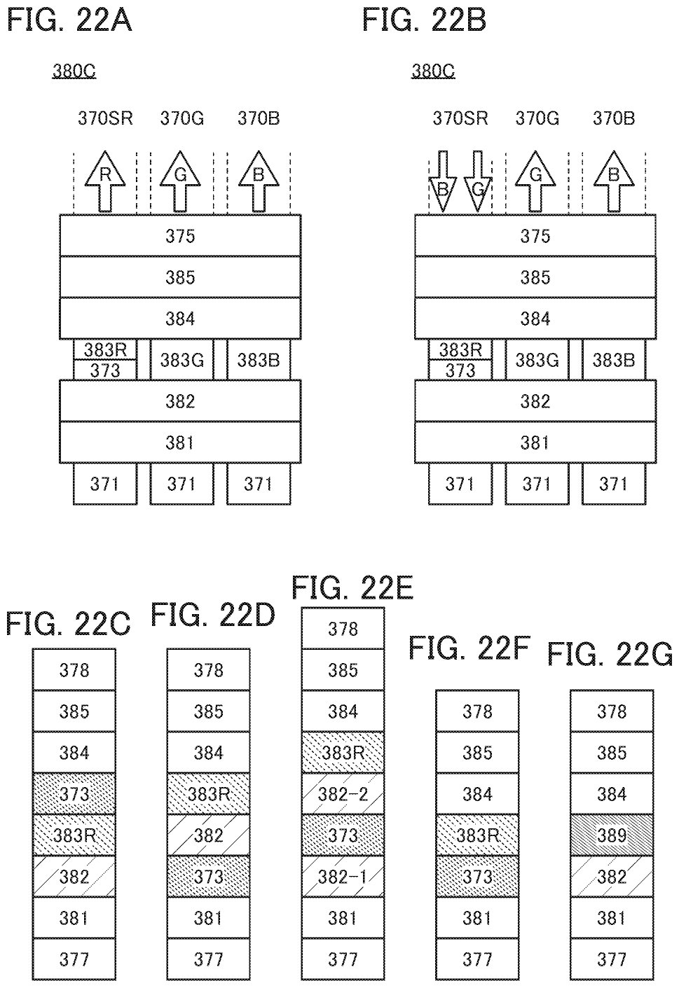

A display device 380C illustrated in FIG. 22A and FIG. 22B includes a light-emitting and light-emitting and light-receiving element 370SR that emits red (R) light and has a light-receiving function, the light-emitting element 370G, and the light-emitting element 370B. The above description of the display device 380A, for example, can be referred to for the structures of the light-emitting element 370G and the light-emitting element 370B.

The light-emitting and light-receiving element 370SR includes the pixel electrode 371, the hole-injection layer 381, the hole-transport layer 382, the active layer 373, the light-emitting layer 383R, the electron-transport layer 384, the electron-injection layer 385, and the common electrode 375, which are stacked in this order. The light-emitting and light-receiving element 370SR has the same structure as the light-emitting element 370R and the light-receiving element 370PD in the display device 380B.

FIG. 22A illustrates a case where the light-emitting and light-receiving element 370SR functions as a light-emitting element. In the example of FIG. 22A, the light-emitting element 370B emits blue light, the light-emitting element 370G emits green light, and the light-emitting and light-receiving element 370SR emits red light.

FIG. 22B illustrates a case where the light-emitting and light-receiving element 370SR functions as a light-receiving element. In the example of FIG. 22B, the light-emitting and light-receiving element 370SR receives blue light emitted by the light-emitting element 370B and green light emitted by the light-emitting element 370G.

The light-emitting element 370B, the light-emitting element 370G, and the light-emitting and light-receiving element 370SR each include the pixel electrode 371 and the common electrode 375. In this embodiment, the case where the pixel electrode 371 functions as an anode and the common electrode 375 functions as a cathode is described as an example. When the light-emitting and light-receiving element 370SR is driven by application of reverse bias between the pixel electrode 371 and the common electrode 375, light incident on the light-emitting and light-receiving element 370SR can be detected and charge can be generated and extracted as current.

It can be said that the light-emitting and light-receiving element 370SR has a structure in which the active layer 373 is added to the light-emitting element. That is, the light-emitting and light-receiving element 370SR can be formed concurrently with the formation of the light-emitting element only by adding a step of forming the active layer 373 in the manufacturing process of the light-emitting element. The light-emitting element and the light-emitting and light-receiving element can be formed over one substrate. Thus, the display portion can be provided with one or both of an image capturing function and a sensing function without a significant increase in the number of manufacturing steps.

The stacking order of the light-emitting layer 383R and the active layer 373 is not limited. FIG. 22A and FIG. 22B each illustrate an example in which the active layer 373 is provided over the hole-transport layer 382, and the light-emitting layer 383R is provided over the active layer 373. The stacking order of the light-emitting layer 383R and the active layer 373 may be reversed.

The light-emitting and light-receiving element may exclude at least one layer of the hole-injection layer 381, the hole-transport layer 382, the electron-transport layer 384, and the electron-injection layer 385. Furthermore, the light-emitting and light-receiving element may include another functional layer such as a hole-blocking layer or an electron-blocking layer.

In the light-emitting and light-receiving element, a conductive film that transmits visible light is used as the electrode through which light is extracted. A conductive film that reflects visible light is preferably used as the electrode through which light is not extracted.

The functions and materials of the layers included in the light-emitting and light-receiving element are similar to those of the layers included in the light-emitting elements and the light-receiving element and are not described in detail.

FIG. 22C to FIG. 22G illustrate examples of stacked-layer structures of light-emitting and light-receiving elements.

The light-emitting and light-receiving element illustrated in FIG. 22C includes a first electrode 377, the hole-injection layer 381, the hole-transport layer 382, the light-emitting layer 383R, the active layer 373, the electron-transport layer 384, the electron-injection layer 385, and a second electrode 378.

FIG. 22C illustrates an example in which the light-emitting layer 383R is provided over the hole-transport layer 382, and the active layer 373 is stacked over the light-emitting layer 383R.

As illustrated in FIG. 22A to FIG. 22C, the active layer 373 and the light-emitting layer 383R may be in contact with each other.

A buffer layer is preferably provided between the active layer 373 and the light-emitting layer 383R. In this case, the buffer layer preferably has a hole-transport property and an electron-transport property. For example, a substance with a bipolar property is preferably used for the buffer layer. Alternatively, as the buffer layer, at least one layer of a hole-injection layer, a hole-transport layer, an electron-transport layer, an electron-injection layer, a hole-blocking layer, an electron-blocking layer, and the like can be used. FIG. 22D illustrates an example in which the hole-transport layer 382 is used as the buffer layer.

The buffer layer provided between the active layer 373 and the light-emitting layer 383R can inhibit transfer of excitation energy from the light-emitting layer 383R to the active layer 373. Furthermore, the buffer layer can also be used to adjust the optical path length (cavity length) of the microcavity structure. Thus, high emission efficiency can be obtained from a light-emitting and light-receiving element including the buffer layer between the active layer 373 and the light-emitting layer 383R.

FIG. 22E illustrates an example of a stacked-layer structure in which a hole-transport layer 382-1, the active layer 373, a hole-transport layer 382-2, and the light-emitting layer 383R are stacked in this order over the hole-injection layer 381. The hole-transport layer 382-2 functions as a buffer layer. The hole-transport layer 382-1 and the hole-transport layer 281-2 may contain the same material or different materials. Instead of the hole-transport layer 281-2, any of the above layers that can be used as the buffer layer may be used. The positions of the active layer 373 and the light-emitting layer 383R may be interchanged.

The light-emitting and light-receiving element illustrated in FIG. 22F is different from the light-emitting and light-receiving element illustrated in FIG. 22A in not including the hole-transport layer 382. In this manner, the light-emitting and light-receiving element may exclude at least one layer of the hole-injection layer 381, the hole-transport layer 382, the electron-transport layer 384, and the electron-injection layer 385. Furthermore, the light-emitting and light-receiving element may include another functional layer such as a hole-blocking layer or an electron-blocking layer.

The light-emitting and light-receiving element illustrated in FIG. 22G is different from the light-emitting and light-receiving element illustrated in FIG. 22A in including a layer 389 serving as both a light-emitting layer and an active layer instead of including the active layer 373 and the light-emitting layer 383R.

As the layer serving as both a light-emitting layer and an active layer, a layer containing three materials which are an n-type semiconductor that can be used for the active layer 373, a p-type semiconductor that can be used for the active layer 373, and a light-emitting substance that can be used for the light-emitting layer 383R can be used, for example.

Note that an absorption band on the lowest energy side of an absorption spectrum of a mixed material of the n-type semiconductor and the p-type semiconductor and a maximum peak of an emission spectrum (PL spectrum) of the light-emitting substance preferably are not overlapped with each other and are further preferably positioned fully apart from each other.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 5

In this embodiment, a metal oxide that can be used in the OS transistor described in the above embodiment is described.

A metal oxide preferably contains at least indium or zinc. In particular, indium and zinc are preferably contained. In addition, in addition to these, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

In addition, the metal oxide can be formed by a sputtering method, a CVD method such as an MOCVD method, an ALD method, or the like.

### <Classification of Crystal Structure>

Amorphous (including completely amorphous), CAAC (c-axis-aligned crystalline), nc (nanocrystalline), CAC (cloud-aligned composite), single-crystal, and polycrystalline (polycrystal) structures can be given as examples of a crystal structure of an oxide semiconductor.

Note that the crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method.

For example, the XRD spectrum of a quartz glass substrate shows a peak with a substantially bilaterally symmetrical shape. On the other hand, the peak of the XRD spectrum of an IGZO film having a crystal structure has a bilaterally asymmetrical shape. The bilaterally asymmetrical peak of the XRD spectrum clearly shows the existence of crystal in the film or the substrate. In other words, the crystal structure of the film or the substrate cannot be regarded as an amorphous state unless it has a bilaterally symmetrical peak in the XRD spectrum.

In addition, the crystal structure of a film or a substrate can also be evaluated with a diffraction pattern obtained by a nanobeam electron diffraction method (NBED) (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the IGZO film deposited at room temperature. Thus, it is suggested that the IGZO film deposited at room temperature is in an intermediate state, which is neither a crystal state nor an amorphous state, and it cannot be concluded that the IGZO film is in an amorphous state.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the CAAC-OS and the nc-OS. Other examples of the non-single-crystal oxide semiconductor include a polycrystalline oxide semiconductor, an amorphous-like oxide semiconductor (a-like OS), an amorphous oxide semiconductor, and the like.

Here, the CAAC-OS, the nc-OS, and the a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of a surface where the CAAC-OS film is formed, or the normal direction of the surface of the CAAC-OS film. In addition, the crystal region refers to a region having periodic atomic arrangement. Note that when atomic arrangement is regarded as lattice arrangement, the crystal region also refers to a region with uniform lattice arrangement. Furthermore, the CAAC-OS has a region where a plurality of crystal regions are connected in an a-b plane direction, and the region has distortion in some cases.

Note that distortion refers to a portion where the direction of lattice arrangement changes between a region with uniform lattice arrangement and another region with uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. Alternatively, in the case where the crystal region is formed of a large number of fine crystals, the size of the crystal region is sometimes approximately several tens of nanometers.

In addition, in an In-M-Zn oxide (the element M is one or more kinds selected from aluminum, gallium, yttrium, tin, titanium, and the like), the CAAC-OS tends to have a layer-shaped crystal structure (also referred to as a layer-shaped structure) in which a layer containing indium (In) and oxygen (hereinafter an In layer) and a layer containing the element M, zinc (Zn), and oxygen (hereinafter an (M,Zn) layer) are stacked. Note that indium and the element M can be replaced with each other. Therefore, indium is sometimes contained in the (M,Zn) layer. Furthermore, the element M is sometimes contained in the In layer. Note that Zn is sometimes contained in the In layer. Such a layer-shaped structure is observed as a lattice image in a high-resolution TEM (Transmission Electron Microscope) image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) might fluctuate depending on the kind, composition, or the like of the metal element contained in the CAAC-OS.

In addition, for example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, lattice arrangement in the crystal region is basically hexagonal lattice arrangement; however, a unit lattice is not always a regular hexagon and is a non-regular hexagon in some cases. In addition, pentagonal lattice arrangement, heptagonal lattice arrangement, and the like are included in the distortion in some cases. Note that a clear grain boundary cannot be observed even in the vicinity of the distortion in the CAAC-OS. That is, it is found that formation of a grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear grain boundary is observed is what is called polycrystal. It is highly probable that the grain boundary becomes a recombination center and captures carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, it can be said that a reduction in electron mobility due to the grain boundary is unlikely to occur. In addition, entry of impurities, formation of defects, or the like might decrease the crystallinity of an oxide semiconductor. This means that the CAAC-OS can also be referred to as an oxide semiconductor having small amounts of impurities and defects (oxygen vacancies or the like). Therefore, physical properties of an oxide semiconductor including the CAAC-OS become stable. Accordingly, the oxide semiconductor including the CAAC-OS is resistant to heat and has high reliability. In addition, the CAAC-OS is also stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region greater than or equal to 1 nm and less than or equal to 10 nm, in particular, a region greater than or equal to 1 nm and less than or equal to 3 nm) has periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. In addition, there is no regularity of crystal orientation between different nanocrystals in the nc-OS. Hence, the orientation in the whole film is not observed. Accordingly, in some cases, the nc-OS cannot be distinguished from an a-like OS or an amorphous oxide semiconductor, depending on the analysis method. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are obtained in the observed electron diffraction pattern when the nc-OS film is subjected to electron diffraction (also referred to as nanobeam electron diffraction) using an electron beam with a probe diameter close to or smaller than the size of a nanocrystal (e.g., greater than or equal to 1 nm and less than or equal to 30 nm).

### [A-Like OS]

The a-like OS is an oxide semiconductor having a structure between those of the nc-OS and the amorphous oxide semiconductor. The a-like OS has a void or a low-density region. That is, the a-like OS has lower crystallinity than the nc-OS and the CAAC-OS. Moreover, the a-like OS has higher hydrogen concentration in the film than the nc-OS and the CAAC-OS.

### <<Composition of Oxide Semiconductor>>

Next, the CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. Alternatively, for example, the first region has higher [In] and lower [Ga] than the second region. Moreover, the second region has higher [Ga] and lower [In] than the first region.

Specifically, the first region includes indium oxide, indium zinc oxide, or the like as its main component. In addition, the second region includes gallium oxide, gallium zinc oxide, or the like as its main component. That is, the first region can be referred to as a region containing In as its main component. Furthermore, the second region can be referred to as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure in which metal elements are unevenly distributed.

The CAC-OS can be formed by a sputtering method under a condition where a substrate is not heated intentionally, for example. Furthermore, in the case where the CAC-OS is formed by a sputtering method, any one or more selected from an inert gas (typically, argon), an oxygen gas, and a nitrogen gas is used as a deposition gas. Moreover, the ratio of the flow rate of an oxygen gas to the total flow rate of the deposition gas at the time of deposition is preferably as low as possible, and for example, the ratio of the flow rate of an oxygen gas to the total flow rate of the deposition gas at the time of deposition is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

By contrast, the second region has a higher insulating property than the first region. In other words, when the second regions are distributed in a metal oxide, leakage current can be inhibited.

In the case where the CAC-OS is used for a transistor, a switching function (On/Off function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Ion), high field-effect mobility (μ), and excellent switching operation can be achieved.

In addition, a transistor using the CAC-OS has high reliability. Thus, the CAC-OS is most suitable for a variety of semiconductor devices such as display devices.

Oxide semiconductors have various structures and each have different properties. Two or more kinds among the amorphous oxide semiconductor, the polycrystalline oxide semiconductor, the a-like OS, the CAC-OS, the nc-OS, and the CAAC-OS may be included in an oxide semiconductor according to one embodiment of the present invention.

### <Transistor Including Oxide Semiconductor>

Next, the case where the oxide semiconductor is used for a transistor is described.

When the oxide semiconductor is used for a transistor, a transistor with high field-effect mobility can be achieved. In addition, a highly reliable transistor can be achieved.

An oxide semiconductor having a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. Note that in the case where the carrier concentration of an oxide semiconductor film is lowered, the impurity concentration in the oxide semiconductor film is lowered to decrease the density of defect states. In this specification and the like, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

In addition, a highly purified intrinsic or substantially highly purified intrinsic oxide semiconductor film has a low density of defect states and accordingly has a low density of trap states in some cases.

In addition, electric charge captured by the trap states in an oxide semiconductor takes a long time to disappear and might behave like fixed electric charge. Thus, a transistor whose channel formation region is formed in an oxide semiconductor having a high density of trap states has unstable electrical characteristics in some cases.

Accordingly, in order to stabilize electrical characteristics of the transistor, reducing the concentration in the oxide semiconductor is effective. In addition, in order to reduce the impurity concentration in the oxide semiconductor, the impurity concentration in a film that is adjacent to the oxide semiconductor is also preferably reduced. Examples of impurities include hydrogen, nitrogen, an alkali metal, an alkaline earth metal, iron, nickel, silicon, and the like.

### <Impurities>

Here, the influence of each impurity in the oxide semiconductor is described.

When silicon or carbon, which is a Group 14 element, is contained in an oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

In addition, when the oxide semiconductor contains an alkali metal or an alkaline earth metal, defect states are formed and carriers are generated in some cases. Accordingly, a transistor using an oxide semiconductor that contains an alkali metal or an alkaline earth metal tends to have normally-on characteristics. Thus, the concentration of an alkali metal or an alkaline earth metal in the oxide semiconductor that is obtained by SIMS is lower than or equal to 1×10¹⁸ atoms/cm³, preferably lower than or equal to 2×10¹⁶ atoms/cm³.

In addition, an oxide semiconductor containing nitrogen easily becomes n-type by generation of electrons serving as carriers and an increase in carrier concentration. Thus, a transistor using an oxide semiconductor that contains nitrogen as the semiconductor tends to have normally-on characteristics. Alternatively, when nitrogen is contained in the oxide semiconductor, a trap state is sometimes formed. This might make the electrical characteristics of the transistor unstable. Therefore, the concentration of nitrogen in the oxide semiconductor that is obtained by SIMS is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

In addition, hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, in some cases, some hydrogen is bonded to oxygen bonded to a metal atom and generates an electron serving as a carrier. Thus, a transistor using an oxide semiconductor that contains hydrogen tends to have normally-on characteristics. For this reason, hydrogen in the oxide semiconductor is preferably reduced as much as possible. Specifically, the hydrogen concentration in the oxide semiconductor that is obtained by SIMS is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for a channel formation region in a transistor, the transistor can have stable electrical characteristics.

At least part of this embodiment can be implemented in combination with the other embodiments described in this specification as appropriate.

### Embodiment 6

In this embodiment, electronic devices each including a display device according to one embodiment of the present invention will be described.

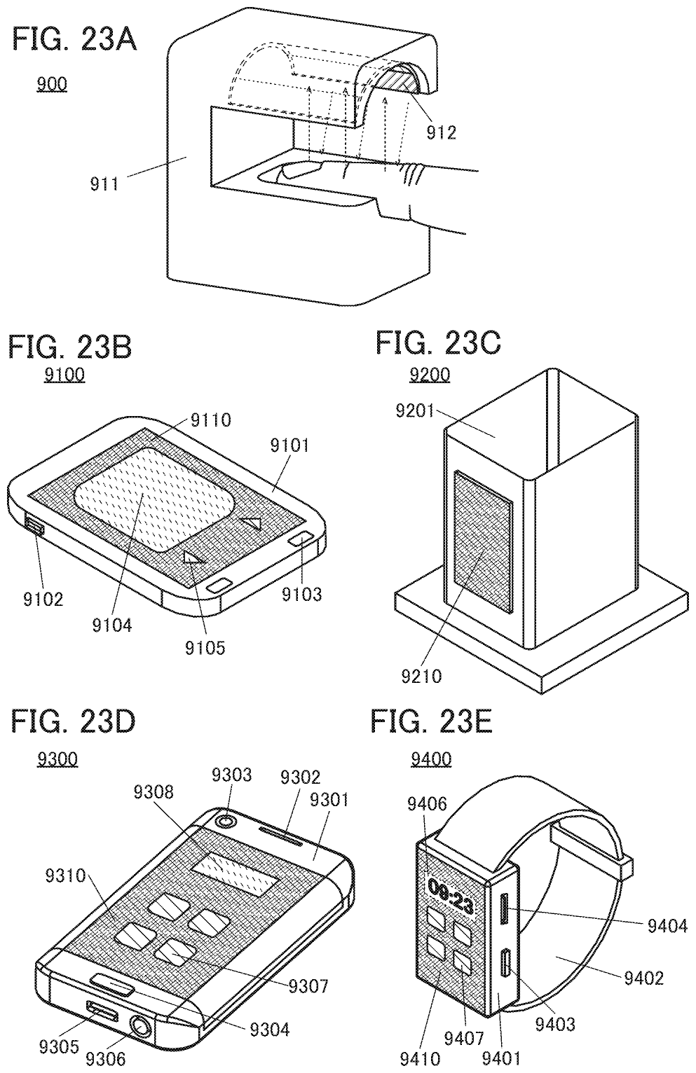

The display device according to one embodiment of the present invention can be provided in a variety of electronic devices. For example, the display device according to one embodiment of the present invention can be provided in a digital camera, a digital video camera, a digital photo frame, a portable game machine, a portable information terminal, an audio reproducing device, or the like, in addition to an electronic device with a comparatively large screen, such as a television device, a desktop or laptop computer, a tablet computer, a monitor for a computer or the like, digital signage, or a large game machine such as a pachinko machine. Structure examples of electronic device in which the display device of one embodiment of the present invention can be provided are described with reference to FIG. 23A to FIG. 23E.

FIG. 23A is a diagram illustrating an example of an oximeter 900. The oximeter 900 includes a housing 911 and a light-emitting and receiving device 912. The housing 911 is provided with a cavity portion, and the light-emitting and receiving device 912 is provided to be in contact with a wall surface of the cavity portion.

The light-emitting and receiving device 912 has a function of a light source that emits light and a function of a sensor that detects light. For example, in the case where an object is put in the cavity portion of the housing 911, light that is emitted by the light-emitting and receiving device 912, irradiates the object, and is reflected by the object can be detected by the light-emitting and receiving device 912.

For example, in the case where a finger is put in the cavity portion of the housing 911, the color of blood is changed depending on oxygen saturation of hemoglobin contained in the blood (the percentage of oxygen-bound hemoglobin). Thus, the intensity of light reflected by the finger that is detected by the light-emitting and receiving device 912 is changed. For example, the intensity of red light that is detected by the light-emitting and receiving device 912 is changed. Accordingly, the oximeter 900 can measure oxygen saturation through detection of the intensity of reflected light by the light-emitting and receiving device 912. The oximeter 900 can be a pulse oximeter, for example.

The display device according to one embodiment of the present invention can be employed in the light-emitting and receiving device 912. In that case, the light-emitting and receiving device 912 includes at least a light-emitting element that emits red light (R). In addition, the light-emitting and receiving device 912 preferably includes a light-emitting element that emits infrared light (IR). There is a large difference between the red light (R) reflectance of oxygen-bound hemoglobin and the red light (R) reflectance of oxygen-unbound hemoglobin. On the other hand, there is a small difference between the infrared light (IR) reflectance of oxygen-bound hemoglobin and the infrared light (IR) reflectance of oxygen-unbound hemoglobin. Therefore, the light-emitting and receiving device 912 includes not only a light-emitting element that emits red light (R) but also a light-emitting element that emits infrared light (IR), so that the oximeter 900 can measure oxygen saturation with high accuracy.

In the case where the display device according to one embodiment of the present invention is employed as the light-emitting and receiving device 912, the light-emitting and receiving device 912 is preferably flexible. When the light-emitting and receiving device 912 is flexible, the light-emitting and receiving device 912 can have a curved shape. Accordingly, for example, the finger can be irradiated with light uniformly, and oxygen saturation can be measured with high accuracy, for example.

FIG. 23B is a diagram illustrating an example of a portable data terminal 9100. The portable data terminal 9100 includes a display portion 9110, a housing 9101, a key 9102, a speaker 9103, and the like. The portable data terminal 9100 can be a tablet, for example. Here, the key such as the key 9102 can be a key for switching the on/off of a power source. That is, the key such as the key 9102 can be a power switch, for example. Alternatively, the key such as the key 9102 can be an operation key to be used to make an electronic device perform a desired operation, for example.

The display portion 9110 can display information 9104, operation buttons (also referred to as operation icons or simply icons) 9105, and the like.

When the display device according to one embodiment of the present invention is provided in the portable data terminal 9100, the display portion 9110 can have a function of a touch sensor or a near touch sensor.

FIG. 23C is a diagram illustrating an example of digital signage 9200. The digital signage 9200 can have a structure where a display portion 9210 is attached to a column 9201.

When the display device according to one embodiment of the present invention is provided in the digital signage 9200, the display portion 9210 can have a function of a touch sensor or a near touch sensor.

FIG. 23D is a diagram illustrating an example of a portable information terminal 9300. The portable information terminal 9300 includes a display portion 9310, a housing 9301, a speaker 9302, a camera 9303, a key 9304, a connection terminal 9305, a connection terminal 9306, and the like. For example, the portable information terminal 9300 can be a smartphone. Note that the connection terminal 9305 can be a micro USB terminal, a lightning terminal, or a Type-C terminal, or the like, for example. In addition, the connection terminal 9306 can be an earphone jack, for example.

The display portion 9310 can display, for example, an operation button 9307. The display portion 9310 can also display information 9308. Examples of the information 9308 include display indicating incoming e-mails, SNS (social networking services), phone calls, and the like; the titles of e-mails, SNS, and the like; the senders of e-mails, SNS, and the like; dates; time; remaining battery; radio field strength; and the like.

When the display device according to one embodiment of the present invention is provided in the portable information terminal 9300, the display portion 9310 can have a function of a touch sensor or a near touch sensor.

FIG. 23E is a diagram illustrating an example of a wristwatch-type portable information terminal 9400. The portable information terminal 9400 includes a display portion 9410, a housing 9401, a wristband 9402, a key 9403, a connection terminal 9404, and the like. Note that the connection terminal 9404 can be a micro USB terminal, a lightning terminal, or a Type-C terminal, or the like, for example, like the connection terminal 9305 or the like.

The display portion 9410 can display information 9406, operation buttons 9407, and the like. FIG. 23E illustrates an example in which time is displayed on the display portion 9410 as the information 9406.

When the display device according to one embodiment of the present invention is provided in the portable information terminal 9400, the display portion 9410 can have a function of a touch sensor or a near touch sensor.

At least part of the structure examples, the drawings corresponding thereto, and the like illustrated in this embodiment can be combined with the other structure examples, the other drawings, and the like as appropriate.

At least part of this embodiment can be implemented in combination with the other embodiments described in this specification as appropriate.

### REFERENCE NUMERALS

10: display device, 10A: display device, 10B: display device, 20: pixel, 51: substrate, 52: finger, 53: layer, 55: layer, 57: layer, 59: substrate, 65: region, 67: fingerprint, 69: contact portion, 71: layer, 73: light-blocking layer, 75: light, 77: light, 80: light-receiving range, 81: light-receiving range, 100: display device, 100A: display device, 100B: display device, 100C: display device, 100D: display device, 100E: display device, 101: substrate, 110: light-emitting element, 110B: light-emitting element, 110G: light-emitting element, 110IR: light-emitting element, 110R: light-emitting element, 111: pixel electrode, 111B: pixel electrode, 111C: connection electrode, 111G: pixel electrode, 111IR: pixel electrode, 111PD: pixel electrode, 111R: pixel electrode, 113: hole-injection layer, 113B: hole-injection layer, 113G: hole-injection layer, 113Gf: functional film, 11318: hole-injection layer, 113R: hole-injection layer, 113Rf: functional film, 115: hole-transport layer, 115B: hole-transport layer, 115G: hole-transport layer, 115Gf: functional film, 1151R: hole-transport layer, 115PD: hole-transport layer, 115R: hole-transport layer, 115Rf: functional film, 117: light-emitting layer, 117B: light-emitting layer, 117G: light-emitting layer, 117Gf: light-emitting film, 11718: light-emitting layer, 117R: light-emitting layer, 117Rf: light-emitting film, 119: electron-transport layer, 119B: electron-transport layer, 119G: electron-transport layer, 119Gf: functional film, 1191R: electron-transport layer, 119PD: electron-transport layer, 119R: electron-transport layer, 119Rf: functional film, 121: common layer, 123: common electrode, 125: protective layer, 127: gap, 130: connection portion, 131: insulating layer, 141: transistor, 141a: sacrificial film, 141b: sacrificial film, 142: transistor, 143: space, 143a: protective film, 143b: protective film, 145a: resist mask, 145b: resist mask, 146: filter, 147a: sacrificial layer, 147b: sacrificial layer, 147c: sacrificial layer, 147d: sacrificial layer, 148: light-blocking layer, 149a: protective layer, 149b: protective layer, 150: light-receiving element, 150L: light-receiving element, 151: substrate, 152: substrate, 153: substrate, 154: substrate, 155: adhesive layer, 156: adhesive layer, 157: light-receiving layer, 158: insulating layer, 162: display portion, 164: circuit, 165: wiring, 166: conductive layer, 172: FPC, 173: IC, 201: transistor, 204: connection portion, 211: insulating layer, 212: insulating layer, 213: insulating layer, 214: insulating layer, 215: insulating layer, 221: conductive layer, 222a: conductive layer, 222b: conductive layer, 223: conductive layer, 228: region, 231: semiconductor layer, 240: capacitor, 241: conductive layer, 242: adhesive layer, 243: insulating layer, 244: connection layer, 245: conductive layer, 251: conductive layer, 252: conductive layer, 254: insulating layer, 255: insulating layer, 256: plug, 261: insulating layer, 262: insulating layer, 263: insulating layer, 264: insulating layer, 265: insulating layer, 271: plug, 274: plug, 274a: conductive layer, 274b: conductive layer, 281-2: hole-transport layer, 301: substrate, 310: transistor, 311: conductive layer, 312: low-resistance region, 313: insulating layer, 314: insulating layer, 315: element isolation layer, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 370B: light-emitting element, 370G: light-emitting element, 370PD: light-receiving element, 370R: light-emitting element, 370SR: light-receiving element, 371: pixel electrode, 373: active layer, 375: common electrode, 377: electrode, 378: electrode, 380A: display device, 380B: display device, 380C: display device, 381: hole-injection layer, 382: hole-transport layer, 382-1: hole-transport layer, 382-2: hole-transport layer, 383: light-emitting layer, 383B: light-emitting layer, 383G: light-emitting layer, 383R: light-emitting layer, 384: electron-transport layer, 385: electron-injection layer, 389: layer, 419: resin layer, 420: substrate, 672: electrode, 686: EL layer, 686a: EL layer, 686b: EL layer, 688: electrode, 900: oximeter, 911: housing, 912: light-emitting and receiving device, 4411: light-emitting layer, 4412: light-emitting layer, 4413: light-emitting layer, 4420: layer, 4420-1: layer, 4420-2: layer, 4430: layer, 4430-1: layer, 4430-2: layer, 9100: portable data terminal, 9101: housing, 9102: key, 9103: speaker, 9104: information, 9110: display portion, 9200: digital signage, 9201: column, 9210: display portion, 9300: portable information terminal, 9301: housing, 9302: speaker, 9303: camera, 9304: key, 9305: connection terminal, 9306: connection terminal, 9307: operation button, 9308: information, 9310: display portion, 9400: portable information terminal, 9401: housing, 9402: wristband, 9403: key, 9404: connection terminal, 9406: information, 9407: operation button, and 9410: display portion.

1. A display device comprising:
a light-emitting element; and
a light-receiving element,
the light-emitting element comprising:
a first pixel electrode;
a first functional layer;
a light-emitting layer;
a common layer; and
a common electrode, and
the light-receiving element comprising:
a second pixel electrode;
a second functional layer;
a light-receiving layer;
the common layer; and
the common electrode,
wherein the first functional layer comprises one of a hole-injection layer and an electron-injection layer,
wherein the second functional layer comprises one of a hole-transport layer and an electron-transport layer, and
wherein in the light-emitting element, the common layer is configured to serve as the other of the hole-injection layer and the electron-injection layer.

2. The display device according to claim 1, wherein the first functional layer and the second functional layer are separated from each other.

3. The display device according to claim 1, further comprising:
a first transistor; and
a second transistor,
wherein one of a source and a drain of the first transistor is electrically connected to the first pixel electrode,
wherein one of a source and a drain of the second transistor is electrically connected to the second pixel electrode, and
wherein the first transistor and the second transistor contain silicon in a channel formation region.

4. The display device according to claim 1, further comprising:
a first transistor; and
a second transistor,
wherein one of a source and a drain of the first transistor is electrically connected to the first pixel electrode,
wherein one of a source and a drain of the second transistor is electrically connected to the second pixel electrode, and
wherein the first transistor and the second transistor contain a metal oxide in a channel formation region.

5. A method for manufacturing a display device, comprising:
a first step of forming a first pixel electrode, a second pixel electrode, and a connection electrode;
a second step of depositing a light-emitting film over the first pixel electrode and the second pixel electrode;
a third step of forming a first sacrificial film over the light-emitting film and the connection electrode;
a fourth step of exposing the second pixel electrode by etching the first sacrificial film and the light-emitting film, and forming a light-emitting layer over the first pixel electrode and a first sacrificial layer over the light-emitting layer and the connection electrode;
a fifth step of depositing a light-receiving film over the light-emitting layer and the second pixel electrode;
a sixth step of forming a second sacrificial film over the light-receiving film and the connection electrode;
a seventh step of, by etching the second sacrificial film and the light-receiving film, forming a light-receiving layer over the second pixel electrode, and forming a second sacrificial layer over the light-receiving layer and the connection electrode;
an eighth step of removing the first sacrificial layer and the second sacrificial layer;
a ninth step of forming a common layer over the light-emitting layer and the light-receiving layer; and
a tenth step of forming a common electrode so that the common electrode comprises a region in contact with the common layer and the connection electrode.

6. The method for manufacturing a display device, according to claim 5, wherein the common layer is configured to serve as one of a hole-injection layer and an electron-injection layer in a light-emitting element comprising the first pixel electrode, the light-emitting layer, the common layer, and the common electrode.

7. The method for manufacturing a display device, according to claim 6,
wherein the method further comprises an eleventh step of depositing a first functional film over the first pixel electrode and the second pixel electrode in a period between the first step and the second step,
wherein in the fourth step, the first functional film is etched to form a first functional layer over the first pixel electrode,
wherein the method further comprises a twelfth step of depositing a second functional film over the first sacrificial layer and the second pixel electrode in a period between the fourth step and the fifth step,
wherein in the seventh step, the second functional film is etched to form a second functional layer over the second pixel electrode,
wherein the first functional layer comprises the other of the hole-injection layer and the electron-injection layer, and
wherein the second functional layer comprises one of a hole-transport layer and an electron-transport layer.

8. The method for manufacturing a display device, according to claim 5, wherein the light-emitting film, the light-receiving film, and the common layer are formed by an evaporation method using a shielding mask.

9. The method for manufacturing a display device, according to claim 5,
wherein the first sacrificial film and the second sacrificial film comprise the same metal film, alloy film, metal oxide film, semiconductor film, or inorganic insulating film,
wherein in the fourth step, the light-emitting film is etched by dry etching using an etching gas that does not contain oxygen as a main component, and
wherein in the eighth step, the first sacrificial layer and the second sacrificial layer are removed by wet etching using a tetramethyl ammonium hydroxide aqueous solution, dilute hydrofluoric acid, oxalic acid, phosphoric acid, acetic acid, nitric acid, or a mixed solution of any of the dilute hydrofluoric acid, the oxalic acid, the phosphoric acid, the acetic acid, and the nitric acid.

10. The method for manufacturing a display device, according to claim 9, wherein the first sacrificial film and the second sacrificial film comprise aluminum oxide.

11. The method for manufacturing a display device, according to claim 5, further comprising a fourteenth step of forming a protective layer over the common electrode after the tenth step.
